(19) United States
(12) Patent Application Publication
(10) Pub. No.: US 2026/0316109 A1
(43) Pub. Date: Oct. 15, 2026

(54) Irrigation Nozzle With Pop-Up Deflector

(71) Applicant: Rain Bird Corporation, Azusa, CA (US)

(72) Inventors: Mateusz Grzegorz Kruzel, Tucson, AZ (US); Michael A. McAfee, Tucson, AZ (US); Jiangjiang Dai, Tucson, AZ (US); Craig David Carroll, Costa Mesa, CA (US)

(21) Appl. No.: 19/175,870

(22) Filed: Apr. 10, 2025

(51) Int. Cl. B05B 15/16; B05B 3/02; B05B 3/04

(52) U.S. Cl. CPC B05B 15/16; B05B 3/027; B05B 3/0426

(57) ABSTRACT

A nozzle is provided with a deflector movable between an extended position and a retracted position, and the deflector has a surface redirecting fluid outwardly from the deflector in the extended position. The nozzle includes a flow path between an inlet and an outlet, and the outlet is oriented to direct exiting fluid against the surface of the deflector. The nozzle may include an arc adjustment valve adjustable to change the size of the outlet for distribution of fluid in an arc of distribution. The nozzle may also include first and second valve surfaces that engage one another to define the outlet when the deflector is in the extended position and that are spaced from one another when the deflector is in the retracted position. The nozzle may further include a radius adjustment valve and/or a pressure regulating system.

### FIELD

This disclosure relates to irrigation nozzles and, more particularly, to an irrigation nozzle with a pop-up deflector.

### BACKGROUND

Nozzles are commonly used for the irrigation of landscape and vegetation. In a typical irrigation system, various types of nozzles are used to distribute water over a desired area. However, these nozzles often utilize narrow flow channels having a small areas, and due to these small areas, they tend to be prone to clogging with grit or debris. It is therefore desirable to include features in the nozzles that limit the accumulation of debris and grit in the nozzles.

Grit or debris may accumulate in nozzles in a variety of circumstances. For example, some nozzles may be buried underground and mounted to a “pop-up” assembly such that they are out of the way when in an inoperative state but “pop up” into an operative state when irrigation is desired. For such nozzles, grit or debris may accumulate in the nozzles when they are in an inoperative state at or below ground level. Alternatively, grit or debris may tend to accumulate in the nozzle by the pop-up actions into an operative state and/or “popping” back down into a retracted state.

Nozzles may include narrow flow channels in the nozzle body that are oriented to direct water against the deflector. Grit or debris can accumulate in the interior of the nozzles and clog the flow channels. When the flow channels clog, the flow of water through the nozzle may be blocked or significantly reduced, and the deflector may cease to rotate. This stalled condition and reduced flow to the deflector may result in non-uniform distribution of water with certain areas being insufficiently watered.

One type of irrigation nozzle is a rotary nozzle having a rotatable deflector with flutes for producing a plurality of relatively small water streams swept over a surrounding terrain to irrigate adjacent vegetation. In such nozzles, water is directed upwardly against the rotatable deflector having a lower surface with curved flutes extending upwardly and turning radially outwardly with a spiral component of direction. The water impinges upon this underside surface of the deflector to fill these curved flutes and to rotatably drive the deflector. At the same time, the water is guided by the curved flutes for projection outwardly from the nozzle in the form of a plurality of relatively small water streams to irrigate a surrounding area. As the deflector is rotatably driven by the impinging water, the water streams are swept over the surrounding terrain area.

Rotary nozzles may be used in various irrigation locations requiring various arcuate shapes of coverage. It is desirable to be able to adjust the extent of the arcuate distribution pattern to cover a specific arcuate area. Otherwise, the rotary nozzle may distribute water to unnecessary areas that do not require irrigation, which may result in a waste of water.

In nozzles with flow channels that may be exposed to grit or debris, it is desirable to address the potential flow of grit and debris into the flow channels to prevent clogging. Further, it is also desirable to divert grit or debris away from the flow channels to limit accumulation in or on the nozzle. Accordingly, there is a need for a nozzle that is structurally configured to limit accumulation of debris and grit in flow channels of the nozzle.

### BRIEF DESCRIPTION OF THE DRAWINGS

FIG. 1A is a perspective view of an embodiment of a nozzle embodying features of the present disclosure with the deflector in a retracted position;

FIG. 1B is a perspective view of the nozzle of FIG. 1A with the deflector in an elevated (or extended) position;

FIG. 2A is a cross-sectional view of the nozzle of FIG. 1A with the deflector in a retracted position;

FIG. 2B is a cross-sectional view of the nozzle of FIG. 1A with the deflector in an elevated position;

FIG. 3 is a top exploded perspective view of the nozzle of FIG. 1A;

FIG. 4 is a bottom exploded perspective view of the nozzle of FIG. 1A;

FIG. 5 is a front elevation view of the valve sleeve and nozzle housing of the nozzle of FIG. 1A;

FIG. 6 is a top plan view of the valve sleeve and nozzle housing of the nozzle of FIG. 1A;

FIG. 7 is a bottom plan view of the valve sleeve and nozzle housing of the nozzle of FIG. 1A;

FIG. 8 is a front perspective view of the nozzle collar, spring support, throttle nut, and piston of the nozzle of FIG. 1A;

FIG. 9 is a top plan view of the nozzle collar, spring support, throttle nut, and piston of the nozzle of FIG. 1A;

FIG. 10 is a bottom perspective view of the nozzle collar, spring support, throttle nut, and piston of the nozzle of FIG. 1A;

FIG. 11 is a perspective view of an embodiment of a nozzle embodying features of the present disclosure with the deflector in an elevated position;

FIG. 12A is a cross-sectional view of the nozzle of FIG. 11 with the deflector in a retracted position;

FIG. 12B is a cross-sectional view of the nozzle of FIG. 11 with the deflector in an elevated position;

FIG. 13 is a front elevation view of the nozzle collar, spring support, throttle nut, and piston of the nozzle of FIG. 11;

FIG. 14 is a cross-sectional view of the nozzle collar, spring support, throttle nut, and piston of the nozzle of FIG. 11;

FIG. 15 is a top plan view of the nozzle collar, spring support, throttle nut, and piston of the nozzle of FIG. 11;

FIG. 16 is a perspective view of an embodiment of a nozzle assembly embodying features of the present disclosure with the deflector in an elevated position;

FIG. 17A is a cross-sectional view of the nozzle assembly of FIG. 16 with the deflector in a retracted position;

FIG. 17B is a cross-sectional view of the nozzle assembly of FIG. 16 with the deflector in an elevated position;

FIG. 17C is a cross-sectional view of the nozzle and the stem seal of the nozzle assembly of FIG. 16 with the deflector in the elevated position without the stem;

FIG. 18 is a front elevation view of the shaft, stem seal, nozzle collar, spring support, sleeve, and piston of the nozzle assembly of FIG. 16;

FIG. 19 is a cross-sectional view of the shaft, stem seal, nozzle collar, spring support, sleeve, and piston of the nozzle assembly of FIG. 16;

FIG. 20 is a top plan view of the shaft, stem seal, nozzle collar, spring support, sleeve, and piston of the nozzle assembly of FIG. 16;

FIG. 21 is a perspective view of an embodiment of a nozzle embodying features of the present disclosure with the deflector in an elevated position;

FIG. 22 is a cross-sectional view of the nozzle of FIG. 21 with the deflector in an elevated position;

FIG. 23 is a perspective view of the deflector and valve sleeve of the nozzle of FIG. 21;

FIG. 24 is a perspective view of the valve sleeve of the nozzle of FIG. 21;

FIG. 25 is a perspective view of the nozzle housing of the nozzle of FIG. 21;

FIG. 26 is a partial cross-sectional view of the nozzle of FIG. 21 showing the shaft, deflector, and other components;

FIG. 27 is a front elevation view of the stator and the shaft of the nozzle of FIG. 21; and

FIG. 28 is a top plan view of the stator and the shaft of the nozzle of FIG. 21.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present disclosure. Also, common but well-understood elements that are useful or necessary in a commercially feasible embodiment are often not depicted in order to facilitate a less obstructed view of these various embodiments of the present disclosure.

### DETAILED DESCRIPTION

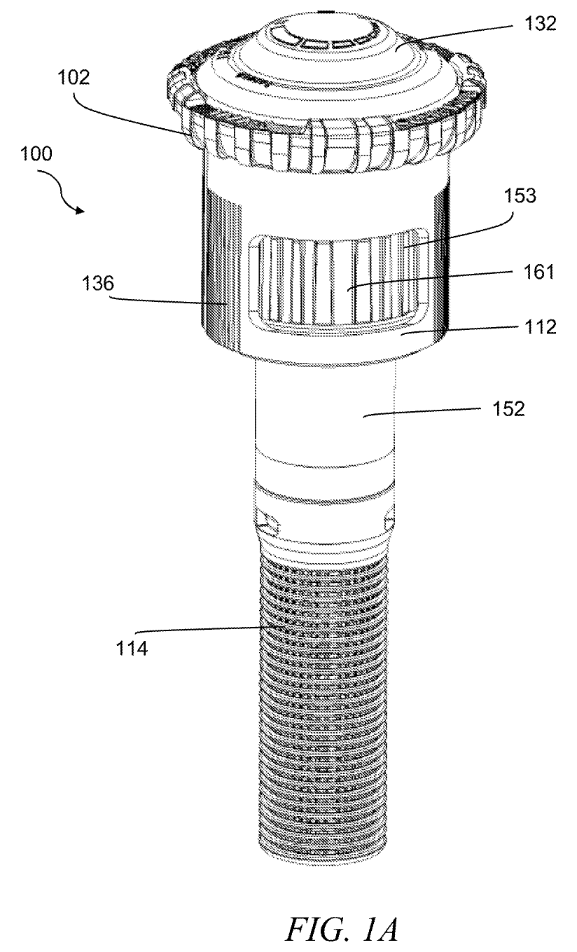

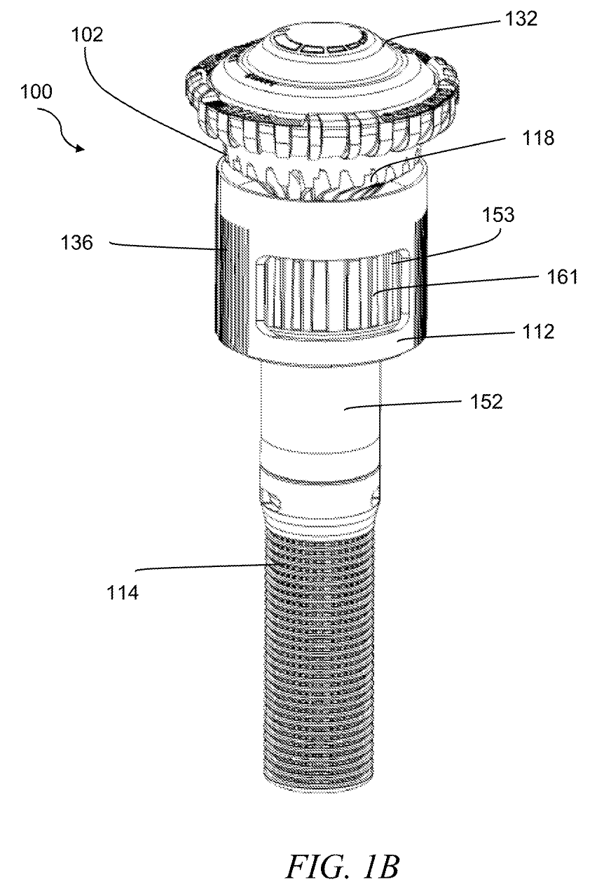

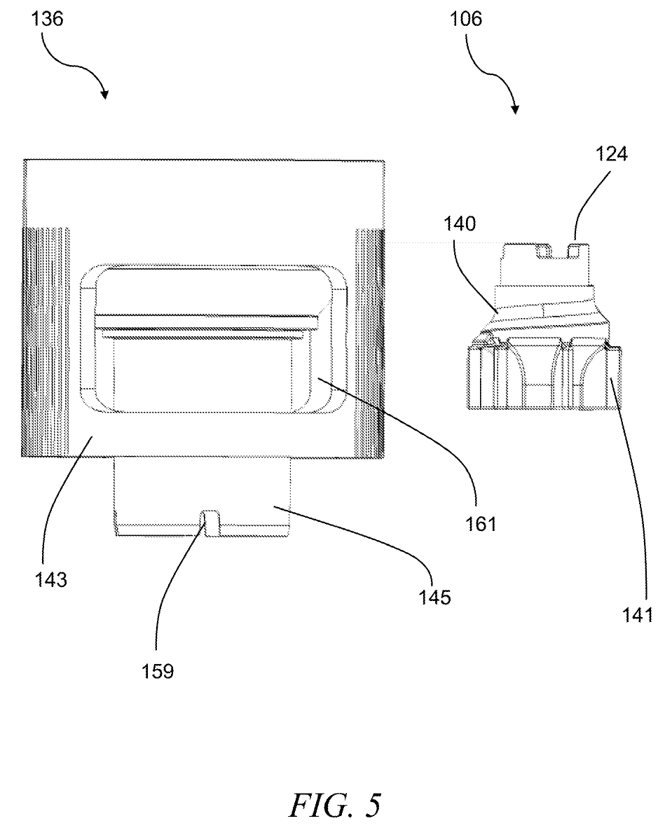

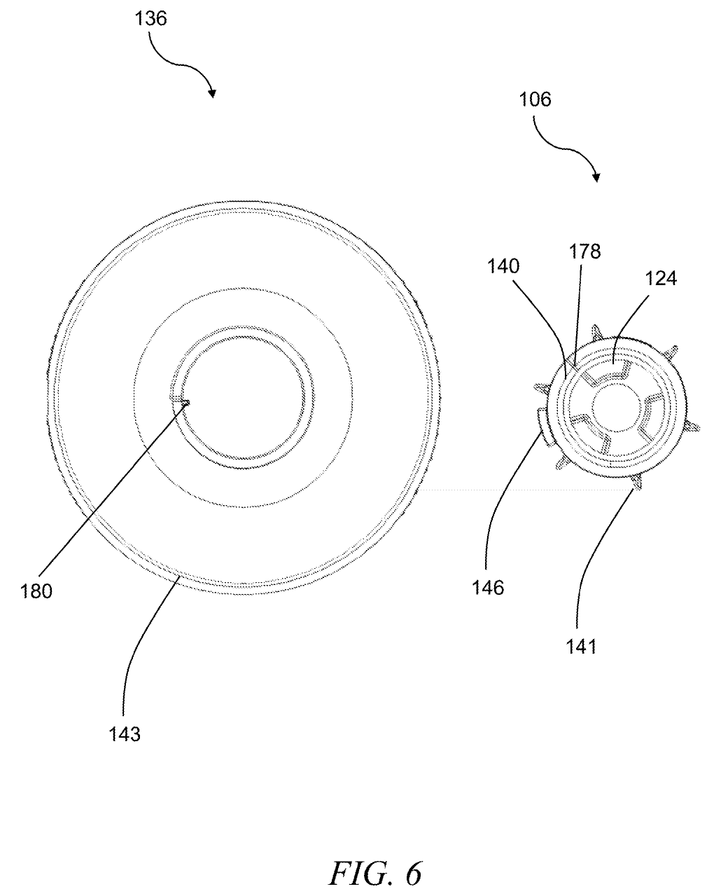

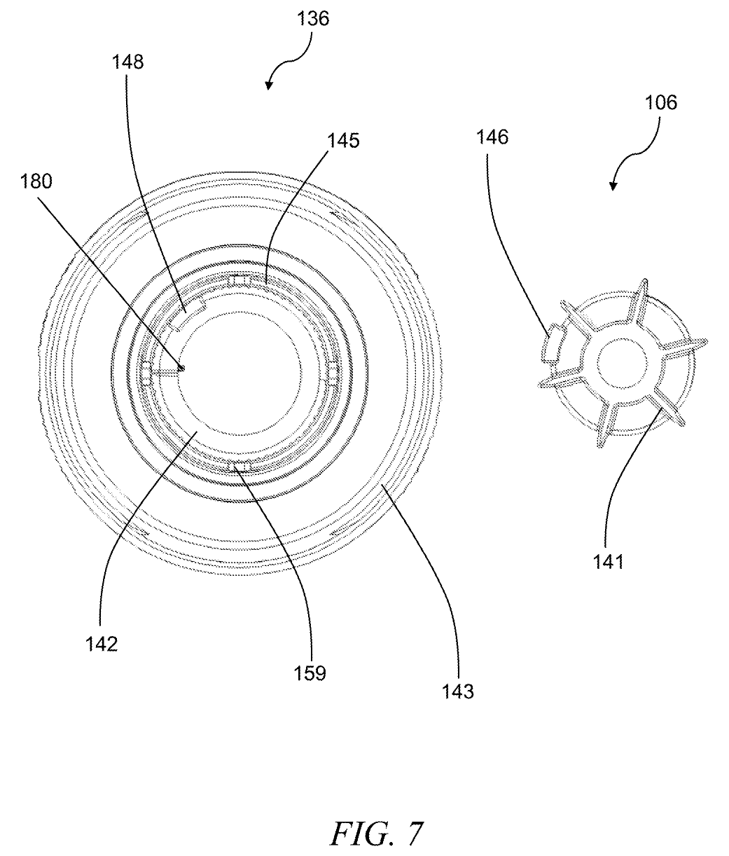

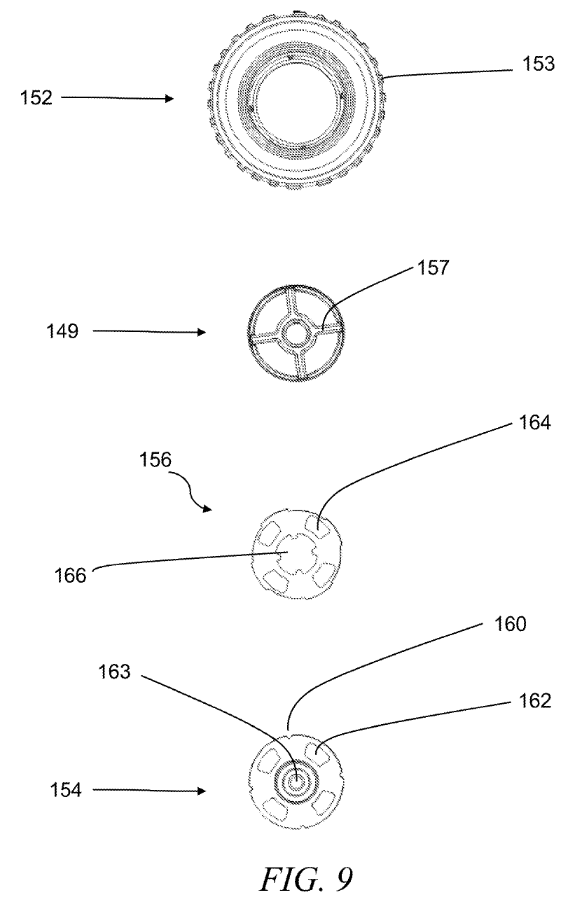

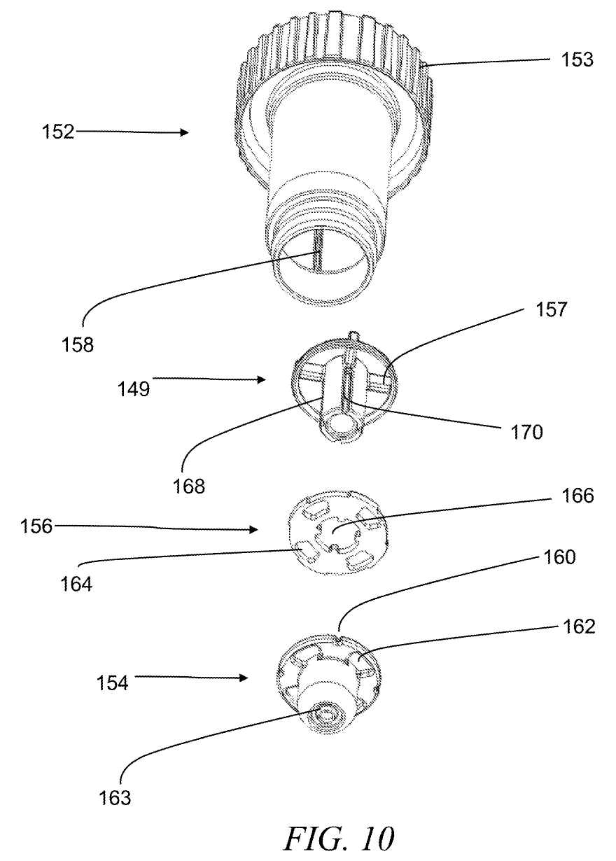

FIGS. 1A-10 show an embodiment of a nozzle 100 and/or components with a “pop-up” feature that embodies aspects of the present disclosure. In one form, the nozzle 100 may include a deflector 102 that moves from a retracted position to a pop-up position in response to the fluid pressure. As addressed below, the movement of this deflector 102 helps protect the nozzle 100 from debris and provides an automatic flushing feature occurring for every cycle of operation.

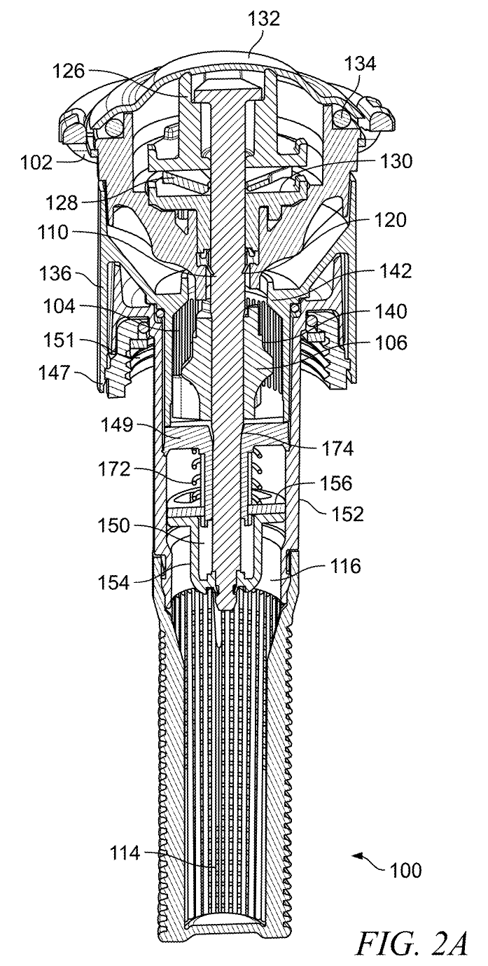

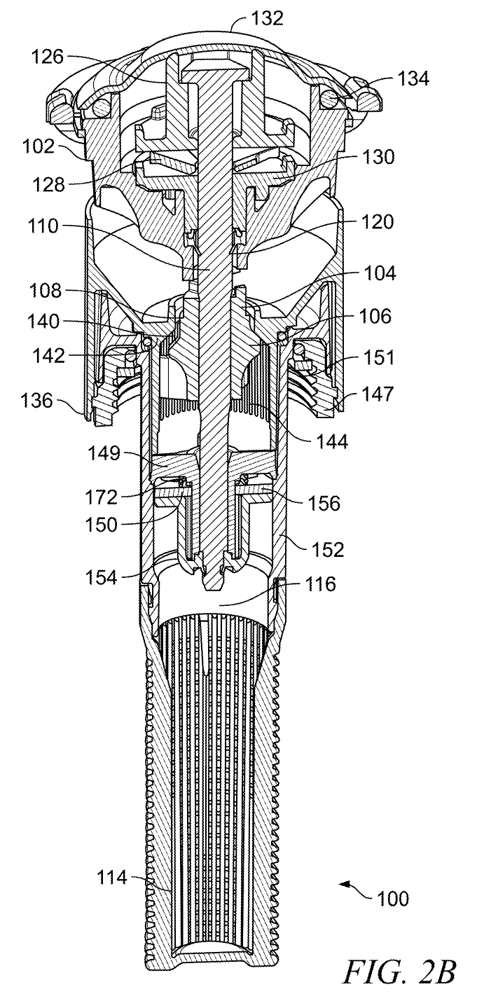

FIGS. 2A and 2B show the nozzle 100 in non-operational and operational positions. In the non-operational position, shown in FIG. 2A, no fluid flows through the nozzle 100. As can be seen, in this non-operational position, the deflector 102 is in a retracted position in which it is covering interior components and preventing debris from entering the interior of the nozzle 100. In the operational position, shown in FIG. 2B, fluid flows through the nozzle 100. As can be seen, in this operational position, the deflector 102 is spaced from the top of nozzle housing 136.

In one form, as addressed below, the nozzle 100 includes a rotatable deflector 102 with flutes for producing a plurality of relatively small water streams swept over a surrounding terrain area to irrigate adjacent vegetation. Further, in one form, the nozzle 100 may include an arc adjustment feature to control an arcuate distribution pattern and a flow rate adjustment (or radius adjustment) feature to adjust the flow and throw of the nozzle 100. Some of the structural components and features of the nozzle 100 are like those described in U.S. Patent No. 8,925,837, issued January 6, 2015; U.S. Patent No. 9,079,202, issued Jul. 14, 2015; U.S. Patent No. 9,295,998, issued Mar. 29, 2016; and U.S. Patent No. 9,327,297, issued May 3,2016; all of which are incorporated by reference herein in their entirety. Differences in the arc adjustment feature, radius adjustment feature, and structural components are addressed below and with reference to the figures. It is also contemplated that the pop-up deflector feature described in this disclosure may be used with other types of nozzles and deflectors, such as, for example, fixed deflector nozzles.

As described in more detail below, in one form, the nozzle 100 allows a user to depress and rotate a deflector 102 to directly actuate the arc adjustment valve 104, i.e., to open and close the valve. The user depresses the deflector 102 to directly engage and rotate one of the two nozzle body portions that forms the valve 104 (valve sleeve 106). The valve 104 preferably operates using two helical engagement surfaces that cam against one another to define an arcuate opening 108 (or arcuate outlet 108 of the nozzle body 112). Although the nozzle 100 preferably includes a shaft 110, the user does not need to use a hand tool to effect rotation of the shaft 110 to open and close the arc adjustment valve 104. The shaft 110 is not rotated to cause opening and closing of the valve 104.

The nozzle 100 generally comprises a compact unit, preferably made primarily of lightweight molded plastic, which is adapted for convenient thread-on mounting onto the upper end of a stationary or pop-up riser. In operation, water under pressure is delivered through the riser to a nozzle body 112. The nozzle body 112 generally refers to the sub-assembly of components disposed between the filter 114 and the deflector 102. The water preferably passes through an inlet 116 controlled by a radius adjustment feature that regulates the amount of fluid flow through the nozzle body 112. Water is then directed generally upwardly through the nozzle body 112, exits an outlet (arcuate opening 108) of the nozzle body 112, and impinges the underside surface of the deflector 102 for rotatably driving the deflector 102.

In one form, the rotatable deflector 102 has an underside surface that is preferably contoured to deliver a plurality of fluid streams generally radially outwardly. As shown in FIG. 1B, the underside surface of the deflector 102 includes an array of flutes 118. The flutes 118 subdivide the water into the plurality of relatively small water streams which are distributed radially outwardly to surrounding terrain as the deflector 102 rotates. The flutes 118 define a plurality of intervening flow channels extending upwardly and radially outwardly along the underside surface with various selected inclination angles. During operation of the nozzle 100, the upwardly directed water impinges upon the lower or upstream segments of these flutes 118, which subdivide the water flow into the plurality of relatively small flow streams for passage through the flow channels and for radially outward projection from the nozzle 100.

In one form, the deflector 102 has a bore 120 for extension of the shaft 110 therethrough. The bore 120 is preferably surrounded at its lower end by circumferentially-arranged, downwardly-protruding teeth 122. As described further below, these teeth 122 are sized to engage corresponding teeth 124 on the valve sleeve 106. In some preferred forms, this engagement allows a user to depress the deflector 102, so that the deflector teeth 122 and valve sleeve teeth 124 engage to set the arc adjustment valve 104 to a desired setting. Although teeth are described, it is also contemplated that other interlocking engagement features may be used to set the arc adjustment valve 104.

The nozzle 100 also preferably includes a speed control brake to control the rotational speed of the deflector 102. In one preferred form shown in FIGS. 2A and 2B, the speed control brake includes a friction disk 126, a brake pad 128, and a seal retainer 130. The friction disk 126 preferably has an internal surface (or socket) for engagement with a top surface (or head) on the shaft 110 to fix the friction disk 126 against rotation relative to the shaft 110. The seal retainer 130 is preferably fastened to, and rotatable with, the deflector 102 and, during operation of the nozzle 100, is urged against the brake pad 128, which, in turn, is retained against the non-rotating friction disk 126.

In one form, water is directed upwardly and strikes the deflector 102, pushing the deflector 102 and seal retainer 130 upwards and causing rotation. In turn, the rotating seal retainer 130 engages the brake pad 128, resulting in frictional resistance that serves to reduce, or brake, the rotational speed of the deflector 102. Speed brakes like the types shown in U.S. Patent No. 9,079,202, issued Jul. 14, 2015, and U.S. Patent No. 10,322,423, issued Jun. 18, 2019, which are incorporated herein by reference in their entirety, may be used. Although a speed control brake is shown and used in connection with nozzle 100 described and claimed herein, other brakes or speed reducing mechanisms are available and may be used to control the rotational speed of the deflector 102. For example, the deflector 102 may include a chamber to hold viscous fluid to reduce the speed of the rotating deflector 102, as addressed further below. The nozzle also may be used without a speed brake.

In one form, the deflector 102 is supported for rotation by shaft 110. Shaft 110 extends along a central axis of the nozzle 100, and the deflector 102 is rotatably mounted on an upper end of the shaft 110. As can be seen from FIGS. 2A and 2B, the shaft 110 extends through the bore 120 in the deflector 102 and through aligned bores in the friction disk 126, brake pad 128, and seal retainer 130, respectively. A cap 132 and o-ring 134 may be mounted to the top of the deflector 102. The cap 132, in conjunction with the o-ring, 134, help to limit grit and other debris from coming into contact with the components in the interior of the deflector sub-assembly, such as the speed control brake components, and thereby hindering the operation of the nozzle 100.

In one form, the variable arc capability of nozzle 100 results from the interaction of two portions of the nozzle body 112 (nozzle housing 136 and valve sleeve 106) in the operational position when fluid is flowing through the nozzle 100. In the operational position, the valve sleeve 106 is urged upwardly by fluid into engagement with a surface of the nozzle housing 136, as addressed further below. The upward fluid pressure helps seal the valve sleeve 106 against the surface of the nozzle housing 136. The nozzle housing 136 and the valve sleeve 106 have corresponding helical engagement surfaces. In the operational position, the valve sleeve 106 may be rotatably adjusted with respect to the nozzle housing 136 to adjust the arc adjustment valve 104, i.e., to adjust the length of arcuate opening 108. In this operational position, the arcuate opening 108 may be adjusted to a desired water distribution arc by the user through push down and rotation of the deflector 102.

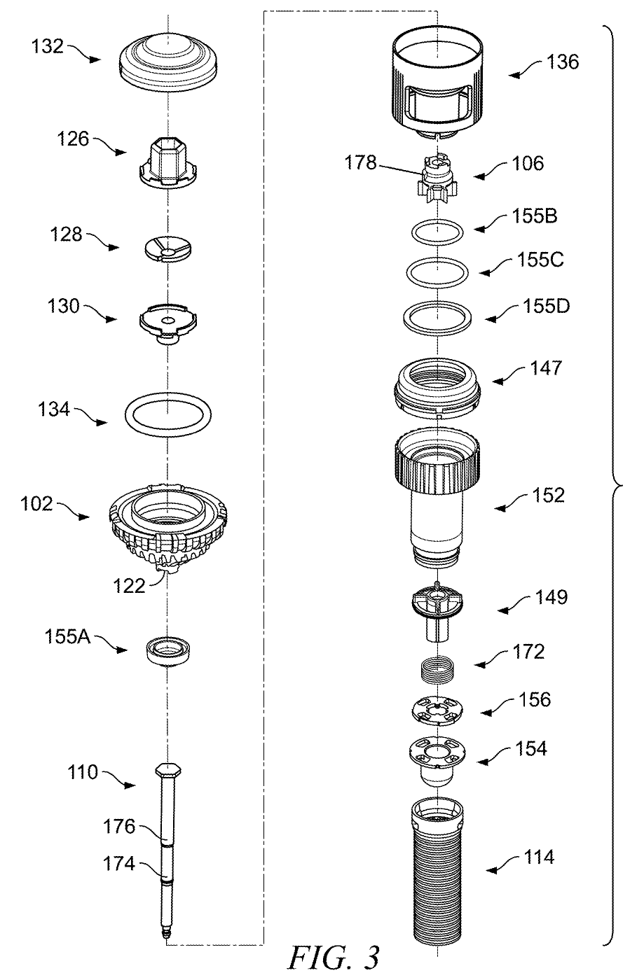

As shown in FIGS. 3-7, in one form, the valve sleeve 106 may have a generally cylindrical shape. The valve sleeve 106 includes a central hub defining a bore through which the shaft 110 extends. The upward force of fluid during operation of the nozzle 100 results in engagement between a helical surface 140 that engages and cams against a corresponding helical surface 142 of the nozzle housing 136 to form the arc adjustment valve 104.

In one form, the nozzle housing 136 includes an outer cylindrical portion 143 and an inner cylindrical portion 145. The interior surface of the inner cylindrical portion 145 includes a grooved surface 144 to guide axial movement of the valve sleeve 106, as addressed below. The bottom end of the inner cylindrical portion 145 is also attached to a spring support 149. As addressed below, the spring support 149 supports the valve sleeve 106 in a non-operational position of the nozzle 100 (no fluid flow through the nozzle 100). The spring support 149 also engages a top end of spring 172 to support the spring 172 as the spring 172 compresses and expands.

Further, in one form, the nozzle housing 136 is attached to a nozzle base 147. The nozzle base 147 is of generally annular shape with internal threading 151 for thread-on mounting onto a threaded upper end of a riser with complementary threading (not shown). The nozzle base 147 and nozzle housing 136 are preferably attached to one another by welding, snap-fit, or other fastening method such that the nozzle housing 136 is stationary relative to the base 147 when the base 147 is threadedly mounted to a riser. In other words, when mounted, the nozzle housing 136 and nozzle base 147 are fixed against rotation.

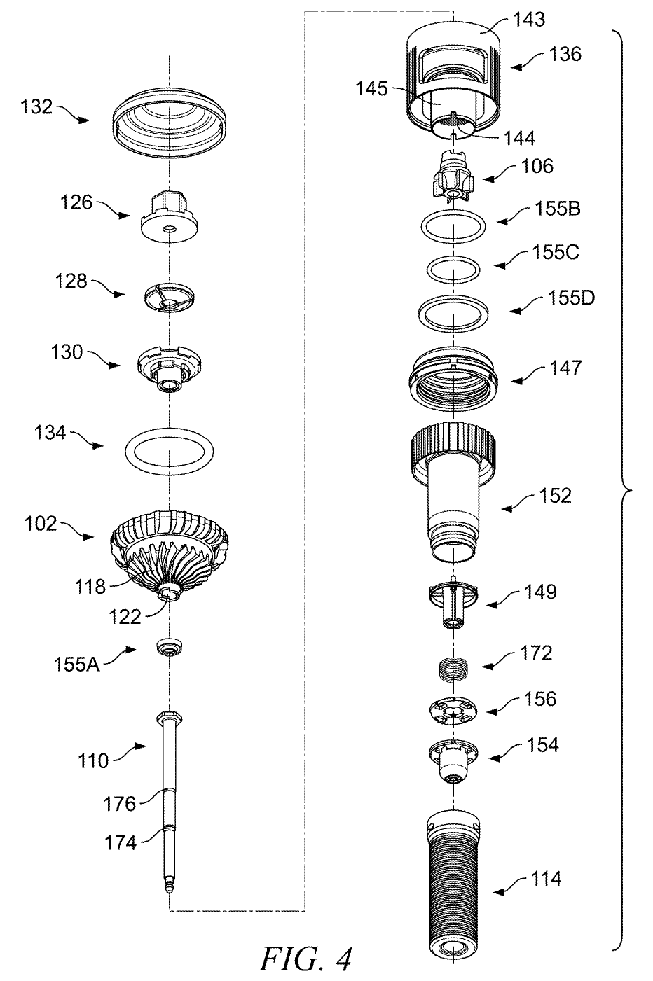

Similarly, in one form, the spring support 149 may be attached to the bottom end of the nozzle housing 136 by any of various fastening methods to fix the spring support 149 against rotation. In one form, the spring support 149 includes radial ribs 157 that are received in corresponding recesses 159 of the nozzle housing 136. The nozzle 100 also preferably includes o-rings or other seal members, such as seal members 155A, 155B, 155C, 155D, at various positions, such as shown in FIGS. 3 and 4, to seal against leakage.

In one form, the helical surfaces 140 and 142 of the valve sleeve 106 and nozzle housing 136 each define approximately one 360-degree helical revolution, or pitch. The valve sleeve 106 also includes radially extending fins 141 that engage the grooved surface 144 on the interior of the nozzle housing 136 to guide upward and downward movement (axial movement) of the valve sleeve 106 between operational and non-operational positions in response to fluid flow. The valve sleeve 106 moves between an engaged position (in which it engages the helical surface 142 of the nozzle housing 136) and a disengaged position (in which it is disengaged from the helical surface 142) in conjunction with movement of the deflector 102. The valve sleeve 106 preferably has a top surface defining teeth 124 formed therein for engagement with the deflector teeth 122 for adjustment of the arc. During adjustment (rotation of the valve sleeve 106 by deflector 102), the fins 141 of the valve sleeve 106 rotate into and out of engagement with specific splines of the non-rotating nozzle housing 136.

In the operational position, the arcuate setting of the nozzle 100 is determined by the relative positions of the helical surface 140 of the valve sleeve 106 and the complementary helical surface 142 of the nozzle housing 136, which act together to form the arcuate opening 108. The camming interaction of the valve sleeve 106 with the nozzle housing 136 forms the arcuate opening 108, as shown in FIG. 2B, where the arc is open on the left side of the FIGURE The length of the arcuate opening 108 is determined by push down and rotation of the deflector 102 (which in turn rotates the valve sleeve 106) relative to the non-rotating nozzle housing 136. The valve sleeve 106 may be rotated relative to the nozzle housing 136 to an arc desired by the user and is not limited to discrete arcs, such as quarter-circle and half-circle.

In some forms, it is contemplated that the nozzle 100 may be operable from a low arcuate setting of about 45 degrees to a fully open arcuate setting of about 360 degrees. It should be evident that the desired direction of rotation of the valve sleeve 106 for either opening or closing the arcuate opening 108 can be easily reversed, i.e., from clockwise to counterclockwise or vice versa, such as by changing the thread orientation of the helical surfaces 140 and 142. Stops 146 and 148 may be included on the valve sleeve 106 and the nozzle housing 136, respectively, to limit movement of the valve sleeve past a certain position, such as, for example, limiting movement to a minimum arc setting of 45 degrees. It should be evident that these stops 146 and 148 may be arranged in other positions relative to one another to provide certain minimum and/or maximum arc settings. In some forms, a first rib 178 may be included on the valve sleeve 106, and a second rib 180 may be included on the nozzle housing 136. These two ribs 178 and 180 help distinctly define the two edges of the arc pattern of coverage.

As shown in FIGS. 2A and 2B, in one form, the nozzle 100 may also include a radius adjustment valve 150. The radius adjustment valve 150 can be used to adjust the fluid flowing through the nozzle 100 for purposes of regulating the range of throw of the projected water streams. It is adapted for variable setting through rotation of the nozzle collar 152. It functions as a valve that is moved between being fully opened and fully closed to change the amount of water flow through the nozzle 100. Also, a filter 114 is preferably located upstream of the radius adjustment valve 150 and attached to a bottom end of the nozzle collar 152, so that it obstructs passage of sizable particulate and other debris that could otherwise damage the nozzle components or compromise desired efficacy of the nozzle 100.

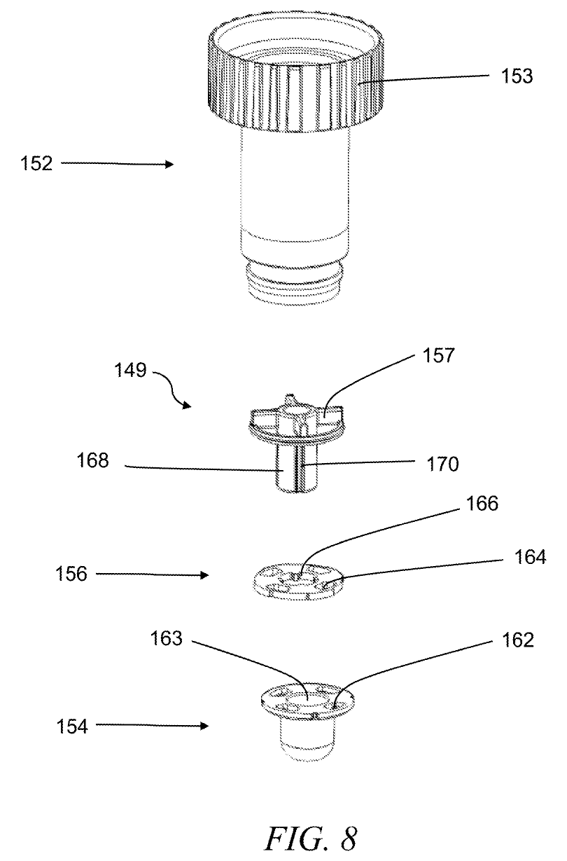

As shown in FIGS. 8-10, in one form, the radius adjustment valve structure may include the nozzle collar 152, the spring support 149, a piston 154, and a throttle nut 156. These components generally include bores for receiving the shaft 110 therethrough. The nozzle collar 152 is preferably cylindrical in shape and includes an outer wall 153 having an external grooved surface for gripping and rotation by a user. In one form, a user can access and rotate this outer wall 153 via an access window 161 in the nozzle housing 136. Water flowing through the inlet 116 passes through the interior of a cylindrical upstream end of the nozzle collar 152 and through the remainder of the nozzle body 112 to the deflector 102. The nozzle collar 152 is rotatable about the central axis of the nozzle 100. Rotation of the outer wall 153 causes rotation of the entire nozzle collar 152.

In one form, the nozzle collar 152 also preferably includes axial ribs 158 at its interior that engage corresponding recesses 160 of the piston 154 (also referred to as a shaft retainer). In one form, the piston 154 includes a bore 163 for receiving and retaining the bottom end of the shaft 110, and it also includes a flat upper surface with a first set of flow openings 162 therethrough. Rotation of the nozzle collar 152 causes rotation of the piston 154 via the engagement of axial ribs 158 and recesses 160.

As can be seen in FIGS. 2A and 2B, the nozzle collar 152 has two different inner diameters. At its upstream end where it engages the filter 114, the nozzle collar 152 has a smaller inner diameter that transitions to a larger inner diameter as one proceeds downstream from the upstream end. This smaller inner diameter at the upstream end allows for fluid pressure that acts on the piston 154 to axially move it from a retracted position to an elevated position, as addressed further below. Then, when the piston 154 is in the elevated position, the larger inner diameter of the nozzle collar 152 facilitates flow through the interior of the nozzle 100 as the pressure drop is shared with the valve sleeve 106, which is urged into engagement with the underside of the nozzle housing 136.

In one form, the throttle nut 156 is in the shape of a plate with a second set of flow openings 164 therethrough. The throttle nut 156 is disposed directly downstream of the piston 154 and upstream of the radial ribs 157 of the spring support 149. The throttle nut 156 also includes a bore 166 that is shaped to receive a post 168 of the non-rotatable spring support 149. The post 168 of the non-rotatable spring support 149 includes axial ribs 170 that fix the throttle nut 156 against rotation.

In combination, the piston 154 and the throttle nut 156 act like a shutter to block and unblock the two sets of flow openings 162 and 164. The nozzle collar 152 may be rotated (to rotate the piston 154) so that the two sets of flow openings 162 and 164 are fully aligned with one another. This orientation corresponds to maximum flow and a maximum throw radius. The nozzle collar 152 may be further rotated (to rotate the piston 154) so that the throttle nut 156 partially or completely blocks the first set of flow openings 162 to reduce the flow and throw radius. In other words, the throttle nut 156 partially or completely blocks flow when the two sets of flow openings 162 and 164 are partially or completely non-aligned. In some forms, the two sets of flow openings 162 and 164 may be sized and arranged so that the throttle nut 156 does not completely block the first set of flow openings 162 in any position, and there is, at least, a minimum flow through the flow openings 162 and 164. The size and cross-section of the flow openings 162 and 164 may be selected as desired to achieve a desired flow and throw radius range. Although this type of radius adjustment valve 150 is described herein, it is contemplated that other types of radius adjustment valves may also be used, such as, for example, described below.

Next, the operation of the nozzle 100 and axial movement between non-operational and operational positions is described. FIG. 2A shows the nozzle in a non-operational position in which there is no fluid flow through the nozzle 100. As can be seen, in this non-operational position, the deflector 102 and cap 132 are disposed to cover the interior of the nozzle housing 136 and the flow channels therein. This non-operational position limits grit and debris that might otherwise clog the nozzle 100. Certain components move axially, i.e., they translate up and down, as the nozzle 100 shifts between non-operational and operational orientations.

In this non-operational position, in one form, some of the components described above are in a retracted position. For example, the deflector subassembly, including the deflector 102 and components therein, and the shaft 110 on which the deflector 102 is mounted, are in a retracted position. A first shoulder 174 of the shaft 110 may engage the spring support 149 to maintain the shaft 110 in its retracted position. Also, the valve sleeve 106 is in a retracted position in which its helical surface 140 is spaced from the helical surface 142 of the nozzle housing 136. In this position, the valve sleeve 106 engages and is supported by the spring support 149. A second shoulder 176 of the shaft 110 disposed near the top of the valve sleeve 106 maintains the valve sleeve 106 in its retracted position. Further, the piston 154 and the throttle nut 156 are in a retracted position. In one form, a spring 172 is disposed between the throttle nut 156 and the radial ribs 157 of the spring support 149, and it generally biases the above components to these retracted positions. In one aspect, the spring 172 helps control movement of these components as they move between retracted and elevated positions. The spring 172 may be a helical spring, although other types are also possible.

FIG. 2B shows the nozzle 100 in an operational position in which fluid is flowing through the nozzle 100. As can be seen, in this operational position, in one form, the deflector 102 is spaced from the top of nozzle housing 136. In this operational position, as was described above, fluid impacts the deflector 102 and is directed outwardly from the deflector 102. In the flow path through the nozzle 100, fluid flows through the filter 114, through the inlet 116 at the bottom end of the nozzle collar 152, through the first and second sets of flow openings 162 and 164 of the radius adjustment valve 150, through the inside of the nozzle housing 136, through the arcuate opening/outlet 108 defined by the valve sleeve 106 and nozzle housing 136, and impacts a surface of the deflector 102 where it is redirected radially outwardly from the nozzle 100. In some forms, although both the arc adjustment valve 104 and radius adjustment valve 150 are described, it is contemplated that the nozzle 100 may use the pop-up features with just one of the arc adjustment valve 104 and the radius adjustment valve 150.

Further, in this operational position, the components described above move axially to elevated, pop-up, or extended, positions. Upward fluid flow through the nozzle 100 overcomes the bias of spring 172 to move the components axially to elevated positions. For example, the deflector subassembly, including the deflector 102 and components therein, and the shaft 110 on which the deflector 102 is mounted, all move to elevated positions. Also, the valve sleeve 106 moved to an elevated position in which its helical surface 140 engages the helical surface 142 of the nozzle housing 136. The valve sleeve 106 moves in tandem with the shaft 110. The valve sleeve 106 is guided in its upward movement and prevented from rotation by the engagement of its radially extending fins 141 with the grooved surface 144 of the nozzle housing 136.

Further, in this form, the piston 154 and the throttle nut 156 generally move together to elevated positions. The piston 154 is guided upward by the engagement of its recesses 160 with the axial ribs 158 of the nozzle collar 152. The throttle nut 156 is guided upward by its engagement with the post 168 of the spring support 149. In these elevated positions, they are generally spaced from the inlet 116 of the nozzle 100. As can be seen, the spring 172 disposed between the throttle nut 156 and the radial ribs 157 of the spring support 149 is compressed in response to fluid flow. Other components, such as the nozzle housing 136, nozzle collar 152, spring support 149, and nozzle base 147, stay in the same axial positions and do not move axially.

As stated above, in the non-operational position, the deflector 102 is retracted and helps prevent debris from entering the interior of the nozzle 100. In addition, the nozzle 100 undergoes automatic flushing with every pressurization (or irrigation) cycle, which also helps prevent the accumulation of debris in the nozzle 100. More specifically, to the extent there may be debris in the nozzle 100, the interior of the nozzle 100 is flushed at the beginning of every pressurization cycle. When fluid initially flows, the area between the valve sleeve 106 and the nozzle housing 136 is open, i.e., the helical surface 140 of the valve sleeve 106 is spaced from the helical surface 142 of the nozzle housing 136, allowing any debris to be flushed out of the nozzle 100. Then, shortly after pressurization, this space between valve sleeve 106 and nozzle housing 136 is sealed as the valve sleeve 106 is urged upward. In general, this initial burst of water flushes the space between the valve sleeve 106 and the nozzle housing 136 right before and as the deflector 102 is being moved to the operational position.

Although the nozzle 100 undergoes automatic flushing every cycle, in some forms, it is contemplated that the nozzle 100 may also include a manual flushing feature. Manual flushing of the nozzle 100 may be accomplished when the deflector 102 is in a raised operational position. In this position, a user can manually push down on the deflector 102 to cause flushing instead of waiting for the next irrigation cycle. This manual flushing feature may be desirable during adjustment and during initial setup to allow users to flush the unit. In the operational position, the valve sleeve 106 is urged upwardly into engagement with the underside of the nozzle housing 136. During manual flushing, a user may push down on the deflector 102 so that the deflector teeth 122 and valve sleeve teeth 124 engage and cause the valve sleeve 106 to be spaced downwardly away from the underside of the nozzle housing 136. This spacing creates a relatively large gap that allows flushing of the interior of the nozzle 100.

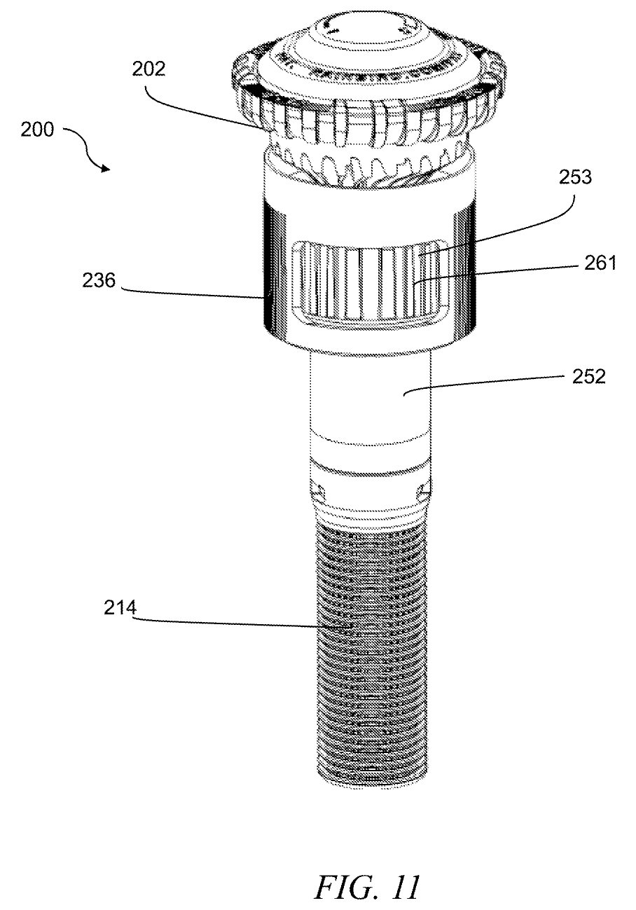

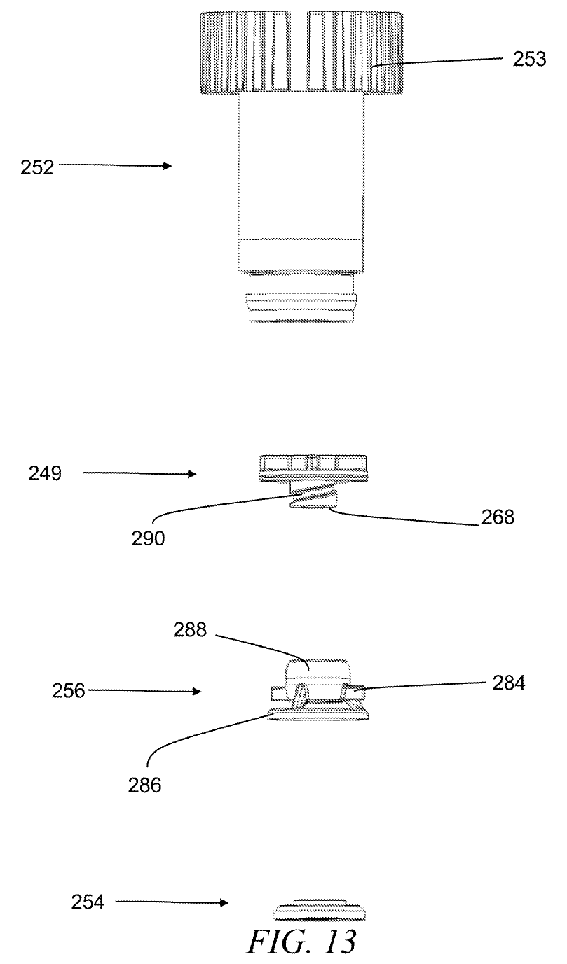

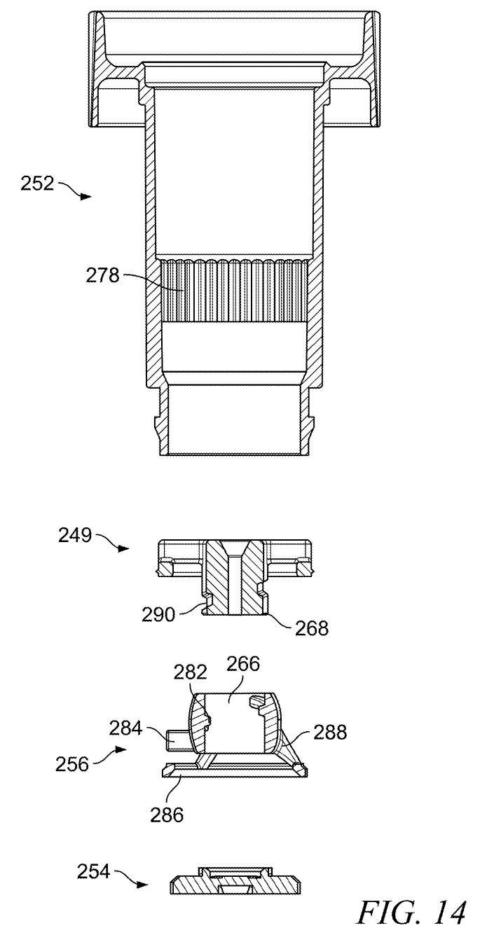

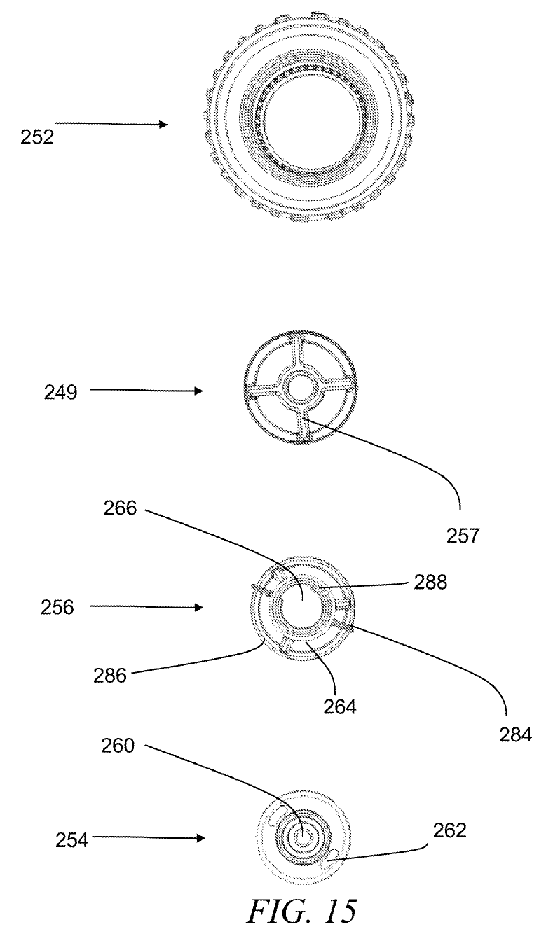

FIGS. 11-15 show another example of a nozzle 200 with a pop-up deflector 202. In one form, the nozzle 200 may include the same or similar components relating to the deflector subassembly and the arc adjustment subassembly. For example, in one form, the nozzle 200 may include the same or similar deflector 202, shaft 210, arc adjustment valve 204, valve sleeve 206, speed brake components (friction disk 226, a brake pad 228, and seal retainer 230), nozzle housing 236, and nozzle base 247. This example is numbered with reference numerals in the 200s corresponding to reference numerals of the previous embodiment. Its pop-up operation is similar to that described above. The above description is generally incorporated into this description of this embodiment, except to the extent noted below.

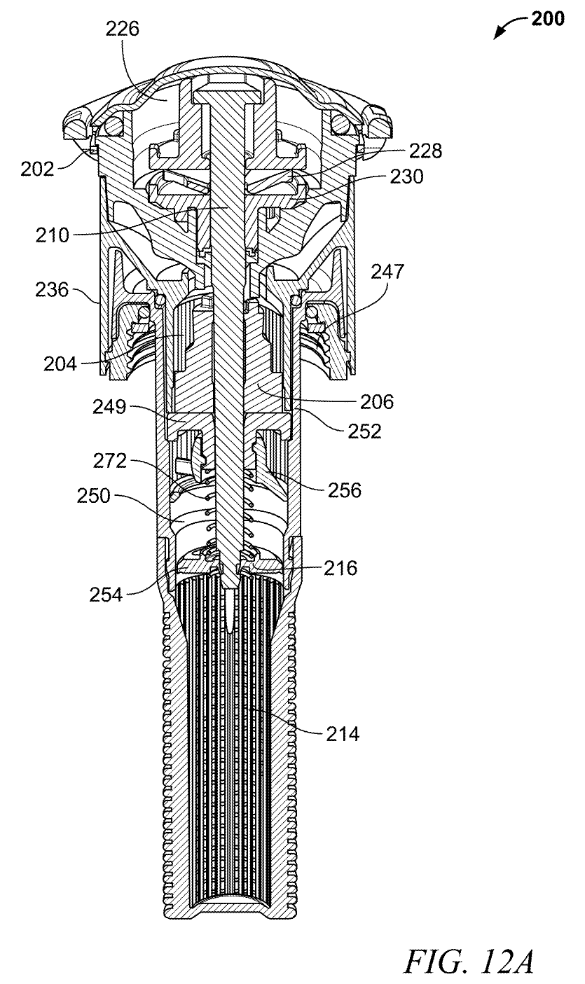

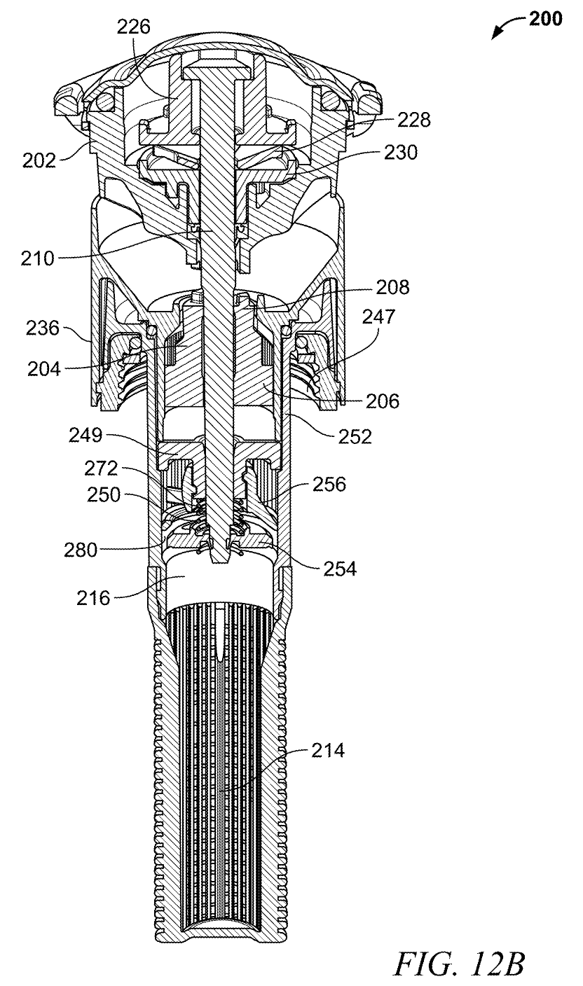

This second example of a nozzle 200 includes modified components relating to radius adjustment/ flow rate adjustment. As shown in FIGS. 12A-15, the nozzle 200 includes a radius adjustment valve 250. The radius adjustment valve structure may again include a nozzle collar 252, a spring support 249, a piston 254, and a throttle nut 256. As addressed below, these components use a throttle nut 256 that moves axially in response to rotation of the nozzle collar 252, instead of a shutter arrangement.

In one form, the nozzle collar 252 has a similar structure and operates in a similar manner to the nozzle collar 152. It is preferably cylindrical in shape and includes an outer wall 253 having an external grooved surface for gripping and rotation by a user. In one form, a user can access and rotate this outer wall 253 via an access window 261 in the nozzle housing 236. The nozzle collar 252 is rotatable about the central axis of the nozzle 200. Rotation of the outer wall 253 causes rotation of the entire nozzle collar 252. It does not move axially between elevated and retracted positions. In contrast to an earlier version (nozzle collar 152), however, it includes a grooved surface 278 (no axial ribs) on the inside of the nozzle collar 252 for engagement with radial fins 284 of the throttle nut 256 to allow axial movement of the throttle nut 256 as described below.

In one form, the piston 254 has a disk-like shape and includes a first set of flow openings 262 therethrough. It also includes a bore 260 for receiving and retaining the bottom end of the shaft 210, and it moves with the shaft 210 between retracted and elevated positions. In the retracted position, as shown in FIG. 12A, it is at the inlet 216 and may engage the nozzle collar 252. Spring 272 is disposed between and engages the piston 254 and the bottom of the spring support 249, and it biases the piston 254 to this retracted position. In the elevated position, in response to fluid flow, as shown in FIG. 12B, it is spaced downstream of the inlet 216, and there is an annular gap 280 between its outer circumference and the inside of the nozzle collar 252.

In one form, the throttle nut 256 is disposed directly downstream of the piston 254 and upstream of the radial ribs 257 of the spring support 249. The throttle nut 256 also includes a bore 266 that is shaped to receive a post 268 of the non-rotatable spring support 249. The throttle nut 256 includes internal threading 282 to engage corresponding external threading 290 on the post 268 to allow rotation and axial movement of the throttle nut 256.

In one form, the throttle nut 256 also includes radial fins 284 that engage the grooved surface 278 of the nozzle collar 252. Rotation of the nozzle collar 252 causes rotation of the throttle nut 256 via the grooved surface 278. When the nozzle collar 252 is rotated, the radial fins 284 move axially while in engagement with the grooved surface 278, thereby allowing the throttle nut 256 to move axially. The throttle nut 256 also includes an outer ring 286 and a central hub 288 (defining bore 266), which reduce flow and throw radius, as described below. In one form, the outer ring 286 and central hub 288 define a second set of flow openings 264.

In combination, in one form, the piston 254 and the throttle nut 256 act to block and unblock the first set of flow openings 262 in the piston 254. The nozzle collar 252 may be rotated (to rotate the throttle nut 256) so that the throttle nut 256 moves up and down (axially) relative to the piston 254. When the throttle nut 256 is spaced downstream from the piston 254, fluid flows through the nozzle 200 and is not blocked.

FIG. 12B shows the nozzle 200 in an operational orientation in which the throttle nut 256 is spaced downstream from the piston 254. This orientation corresponds to maximum flow and a maximum throw radius. In this operational orientation, fluid flows through the annular gap 280 and flows through the first and second set of flow openings 262 and 264. In the flow path through the nozzle 200, fluid flows through the filter 214, through the inlet 216 at the bottom end of the nozzle collar 252, through the annular gap 280 and first and second sets of flow openings 262 and 264 of the radius adjustment valve 250, through the inside of the nozzle housing 236, through the arcuate opening/outlet 208 defined by the valve sleeve 206 and nozzle housing 236, and impacts a surface of the deflector 202 where it is redirected radially outwardly from the nozzle 200. In some forms, although both the arc adjustment valve 204 and radius adjustment valve 250 are described, it is contemplated that the nozzle 200 may use the pop-up features with just one of the arc adjustment valve 204 and the radius adjustment valve 250.

In one form, from the above maximum flow orientation, the nozzle collar 252 may be rotated to rotate the throttle nut 256 to move it axially towards the piston 254. This rotation causes the throttle nut 256 to partially or completely block the annular gap 280 to reduce the flow and throw radius. In one form, flow through the annular gap 280 may be reduced as the throttle nut 256 approaches the piston 254 until an underside surface of the outer ring 286 engages a corresponding upper surface of the piston 254. These underside and upper surfaces may, for example, be beveled surfaces. It is contemplated that, in this position, the first set of flow openings 262 are not obstructed so that there is still some minimum flow, even though the annular gap 280 is blocked.

In other forms, however, the flow may be completely blocked. For example, the first set of flow openings 262 may be removed entirely, or the central hub 288 of the throttle nut 256 may be sized to block the first set of flow openings 262 as the throttle nut 256 approaches the piston 254. In one form, for a lower flow rate nozzle with a shorter throw radius, the first set of flow openings 262 may be omitted entirely, while for a higher flow rate where a longer range is needed, the first set of flow openings 262 may be included. The size and cross-section of the annular gap 280 and first set of flow openings 262 may be selected as desired to achieve a desired flow and throw radius range. Although this type of radius adjustment valve 250 is described herein, it is contemplated that other types of radius adjustment valves may also be used.

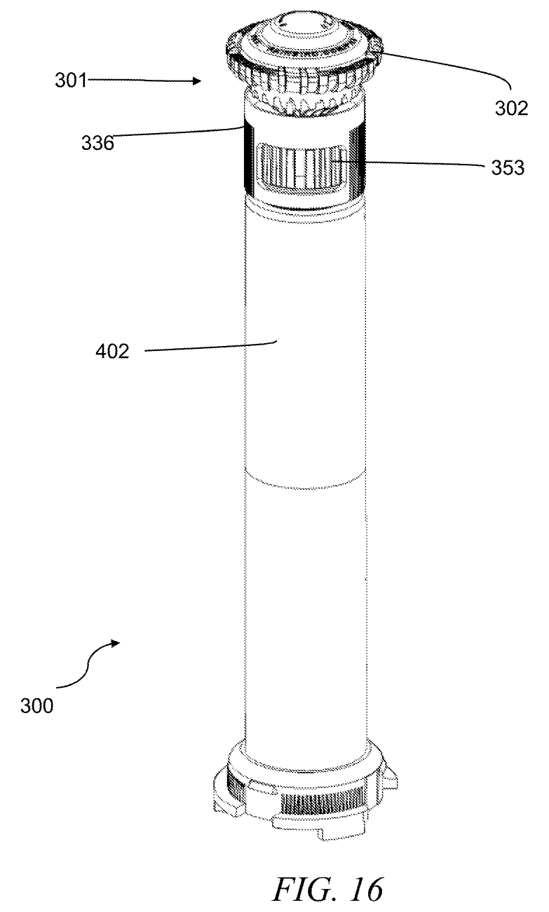

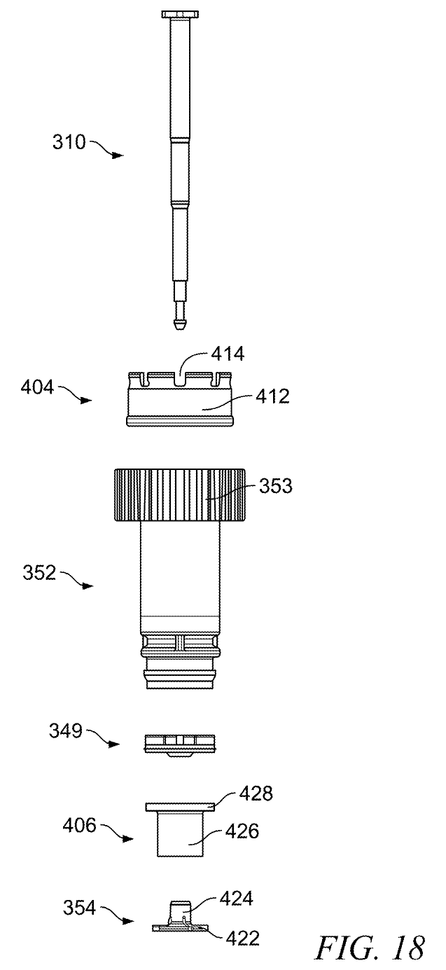

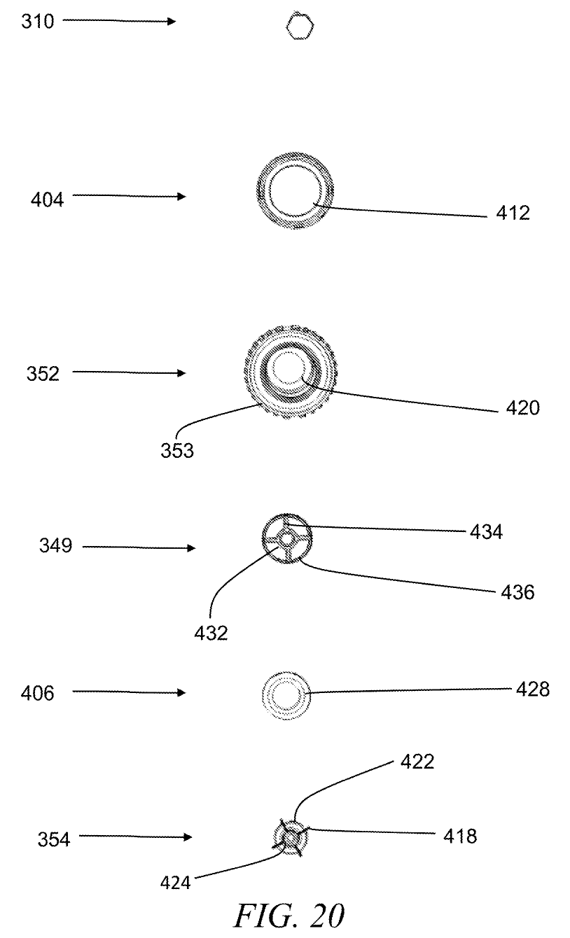

FIGS. 16-20 show an example of a nozzle assembly 300 and nozzle 301 with a pop-up deflector 302. In one form, the nozzle 301 may include the same or similar components relating to the deflector subassembly and the arc adjustment subassembly as in the previous examples. For instance, in one form, the nozzle 301 may include the same or similar deflector 302, arc adjustment valve 304, valve sleeve 306, speed brake components (friction disk 326, a brake pad 328, and seal retainer 330), nozzle housing 336, and nozzle base 347. This embodiment is numbered with reference numerals in the 300s corresponding to reference numerals of the previous examples. Its pop-up operation is similar to that described above. The above description is generally incorporated into this description of this embodiment, except to the extent noted below.

This third example of a nozzle 301 incorporates a pressure regulating system 400 for flow rate adjustment. In one form, the pressure regulating system 400 may be disposed downstream of filter 314 and may maintain a desired fluid pressure at the nozzle 301 despite variations in line pressure. The pressure regulating system 400 may include a stem 402, a stem seal 404, a nozzle collar 352, a piston 354, a pressure regulating sleeve 406, and a second spring 408.

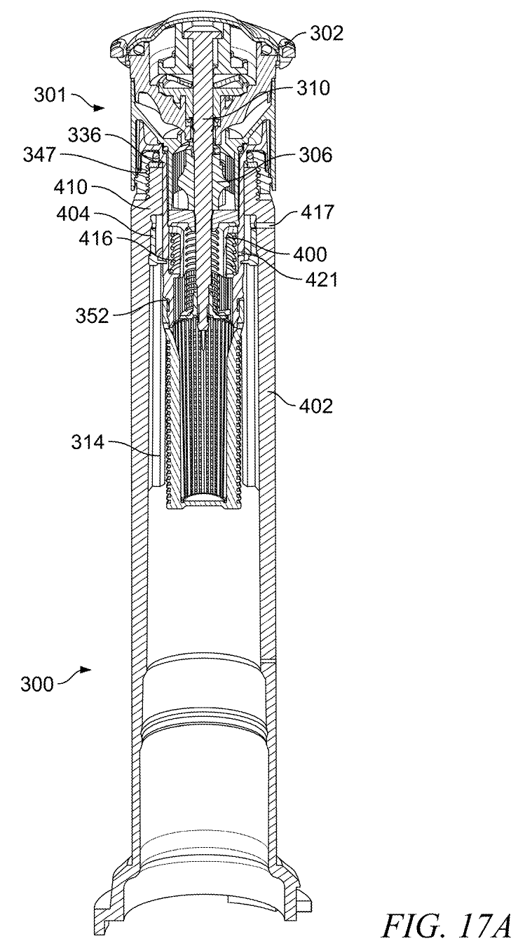

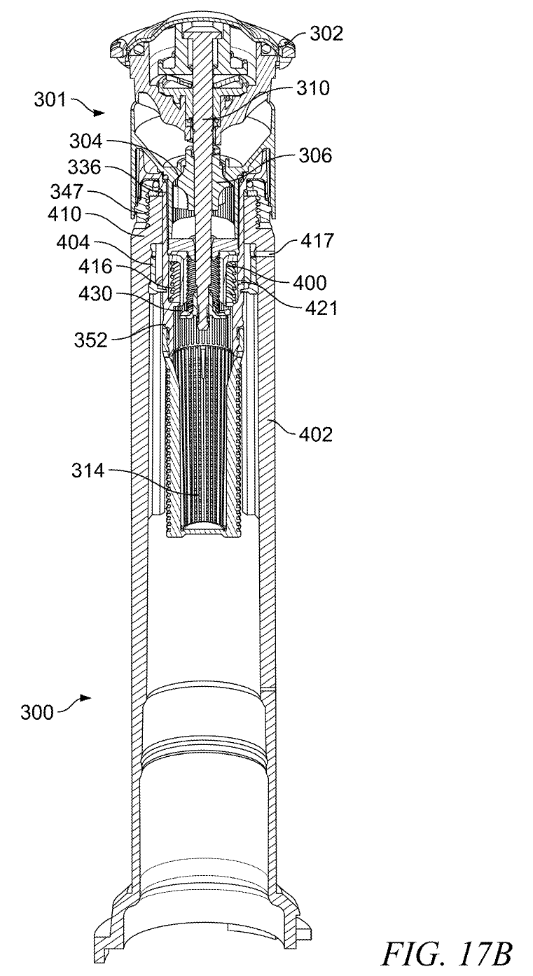

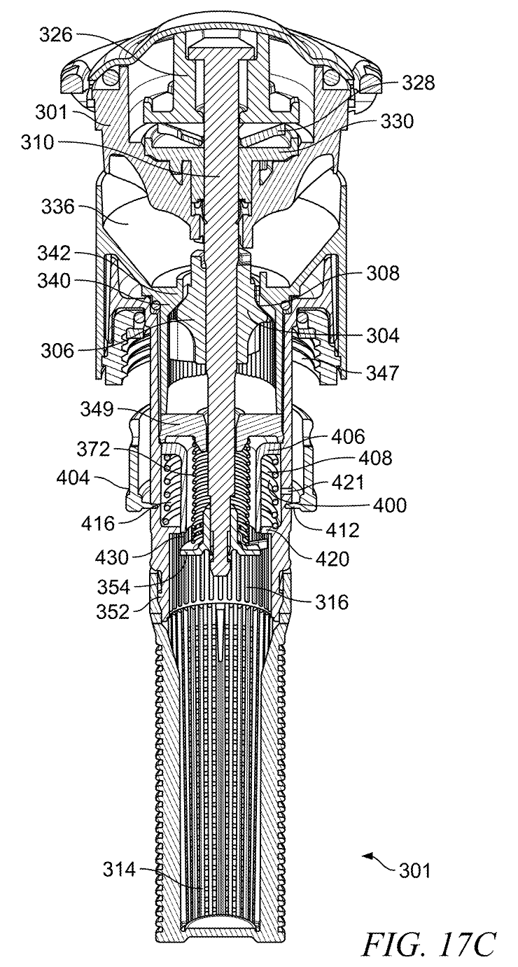

As shown in FIGS. 16-17B, in one form, it is generally contemplated that the nozzle 301 may be mounted on a stem 402. In one form, the nozzle base 347 may be threaded onto an upper threaded end of the stem 402, which serves as a conduit for fluid flowing to the nozzle 301. Fluid flows through the interior of the stem 402 and then through the nozzle 301. It is generally contemplated that the other nozzles 100 and 200 may similarly be mounted to stems. In one form, these stems may be received within spring-loaded riser assemblies that cause the stem 402 to move relative to the remainder of the riser assembly in response to fluid flow. In one form, the nozzle 301 may be mounted on a riser assembly with a stem 402 that initially pops out of the ground in response to fluid pressure (a first pop). The nozzle 301 may also include a deflector 302 that moves from a retracted position to a pop-up position in response to the fluid pressure (a second pop). An example of a riser assembly with a stem and nozzle arrangement is shown and described in U.S. Patent No. 7,644,870, issued January 12, 2010, and U.S. Patent No. 8,833,672, issued September 16, 2014, and U.S. Patent No. 10,322,423, issued June 18, 2019, all of which are incorporated by reference herein in their entirety.

In one form, the pressure regulating system 400 also includes a stem seal 404. The stem seal 404 may be generally annular in shape. It may be mounted in the stem 402 between the stem 402 and the nozzle collar 352 directly beneath a shoulder 410 of the stem 402. The bottom end of the stem seal 404 may define a lip or ledge 412 that engages the nozzle collar 352. The top end of the stem seal 404 may define multiple cut-outs 414 that are spaced circumferentially about the top end. As addressed further below, the position and structure of the stem seal 404 allows venting of air from a pressure chamber 416 in the nozzle 301 through an air passage 417 in the stem 402 to the atmosphere.

In one form, the nozzle collar 352 has a similar structure and operates in a similar manner to nozzle collar 252. It is preferably cylindrical in shape and includes an outer wall 353 having an external grooved surface for gripping and rotation by a user. The nozzle collar 352 is rotatable about the central axis of the nozzle 301. Rotation of the outer wall 353 causes rotation of the entire nozzle collar 352. It includes a grooved surface 378 on the inside of the nozzle collar 352 for engagement with radial fins 418 of the piston 354 to allow axial movement of the piston 354, as described below. In contrast to the earlier examples, however, the nozzle collar 352 may also include an annular rib 420 that projects inwardly and defines a bottom end of the pressure chamber 416, as described below. Also, the nozzle collar 352 includes an opening in the outer wall 353 that defines an air passage 421 from the pressure chamber 416.

In one form, the piston 354 has a lower portion in the shape of a disk 422 with the radial fins 418 extending outwardly from the disk 422. It also includes a central hub 424 that defines a bore 360 for receiving and retaining the bottom end of the shaft 310, and it moves with the shaft 310 between retracted and elevated positions. In the retracted position, as shown in FIG. 17A, it is at the inlet 316 near the top of the filter 314. A first spring 372 is disposed between and engages the piston 354 and the bottom of the spring support 349, and it biases the piston 354 to this retracted position. The spring support 349 may be similar in structure to the earlier embodiments but need not include a post. It may include a central hub 432 defining a bore, spokes 434, and an outer ring 436. When the piston 354 is in the elevated position, in response to fluid flow, as shown in FIGS. 17B and 17C, the piston 354 is spaced downstream of the inlet 316 and the filter 314 and closer to the annular rib 420 of the nozzle collar 352. The diameter of the disk 422 is less than that of the inside of the nozzle collar 352 such that fluid can flow around the outside of disk 422.

In one form, the pressure regulating system 400 also includes a pressure regulating sleeve 406. The pressure regulating sleeve 406 may include a cylindrical portion 426 defining a flow passage 427 therethrough. It may also include a lip or ledge 428 at its downstream end. The pressure regulating sleeve 406 is disposed upstream of the spring support 349, and its ledge 428 engages the spring support 349. In one form, the sleeve’s bottom end engages the annular rib 420 of the nozzle collar 352. As can be seen in FIG. 17C, the pressure regulating sleeve 406, in combination with the nozzle collar 352, defines the pressure chamber 416. A second spring 408 is disposed in the pressure chamber 416.

During operation, in one form, an axial gap 430 between the upstream end of the sleeve 406 and the disk 422 of the piston 354 may be adjusted and/or coordinated with the arc adjustment to adjust simultaneously. During arc adjustment, when the arc is being set to a larger size, the valve sleeve 306 also translates downward, or upstream, as its helical surface 340 engages and cams along the corresponding helical surface 342 of the nozzle housing 336. In turn, the shaft 310 and piston 354 also translate upstream, which increases the size of the axial gap 430. Further, in some forms, the shaft 310 may include external threading to engage corresponding internal threading of the piston 354, which may allow axial movement of the piston 354 along the shaft 310 in response to rotation of the nozzle collar 352. The axial gap is increased as the arcuate extent of the water coverage is increased due to the need for more water to irrigate the larger area.

In addition, during operation, the pressure chamber 416 helps regulate the pressure at the nozzle 301. Fluid flow through the nozzle 301 is adjusted by the pressure regulating sleeve 406 when pressure inside the nozzle 301 acting on the sleeve 406 exceeds the second spring force. In other words, when downward pressure on the ledge 428 of the sleeve 406 exceeds the second spring force, the sleeve 406 is urged downwardly against the bias of the second spring 408. This downward movement of the bottom end of the sleeve 406 decreases the size of the axial gap 430 and decreases flow. The pressure chamber 416 vents air out of the chamber 416 to the atmosphere by the air passage 421 in the nozzle collar 352, one or more cut-outs 414 of the stem seal 404, and the air passage 417 in the stem 402. The size of the axial gap 430 and the second spring 408 may be selected so as to achieve desired regulation pressure, such as, for example, 45 pounds per square inch (psi).

Further, pressure may be regulated by adjustment of the piston 354 relative to shaft 310. In some forms, it is contemplated that the piston 354 may translate axially on the shaft 310. In one form, as stated above, the shaft 310 may include external threading to engage corresponding internal threading of the piston 354 to allow axial movement of the piston 354 along the shaft 310 in response to rotation of the nozzle collar 352 by a user. Adjustment of the piston 354 may be used to regulate pressure. If the piston 354 is adjusted to the downstream (or uppermost) position on the shaft 310, the distance of possible downward travel by the pressure regulating sleeve 406 is reduced, resulting in a lower regulation pressure. In contrast, if the piston 354 is adjusted to the upstream (or lowermost) position, the distance of possible downward travel by the pressure regulation sleeve 406 is increased, resulting in a higher regulation pressure.

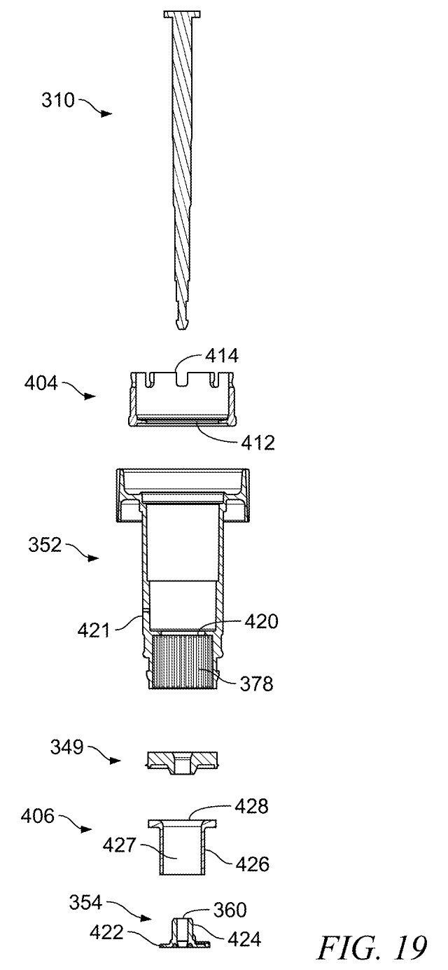

In the flow path, as shown in FIGS. 17B and 17C, fluid flows through stem 402, through the filter 314, through the inlet 316 at the bottom end of the nozzle collar 352, around the outer circumference of the disk 422, through the flow passage 427 (FIG. 19) defined by the sleeve 406, through the inside of the nozzle housing 336, through the arcuate opening/outlet 308 defined by the valve sleeve 306 and nozzle housing 336, and impacts a surface of the deflector 302 where it is redirected radially outwardly from the nozzle 301. In some forms, it is contemplated that the nozzle 301 may use the pop-up features without the arc adjustment valve 304. In other words, the nozzle 301 may include a pop-up deflector and a pressure regulating system without any arc adjustment valve (or with a different type of arc adjustment valve). For example, in some forms, it is contemplated that the nozzle 301 may include a pop-up deflector, a pressure regulating system, and fixed arc component(s) that provide full circle distribution, half circle distribution, etc.

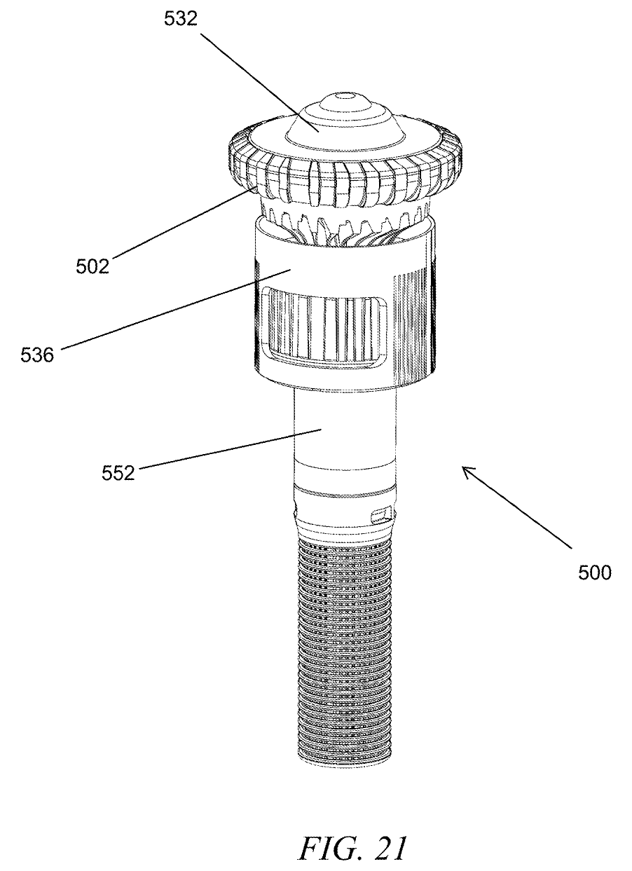

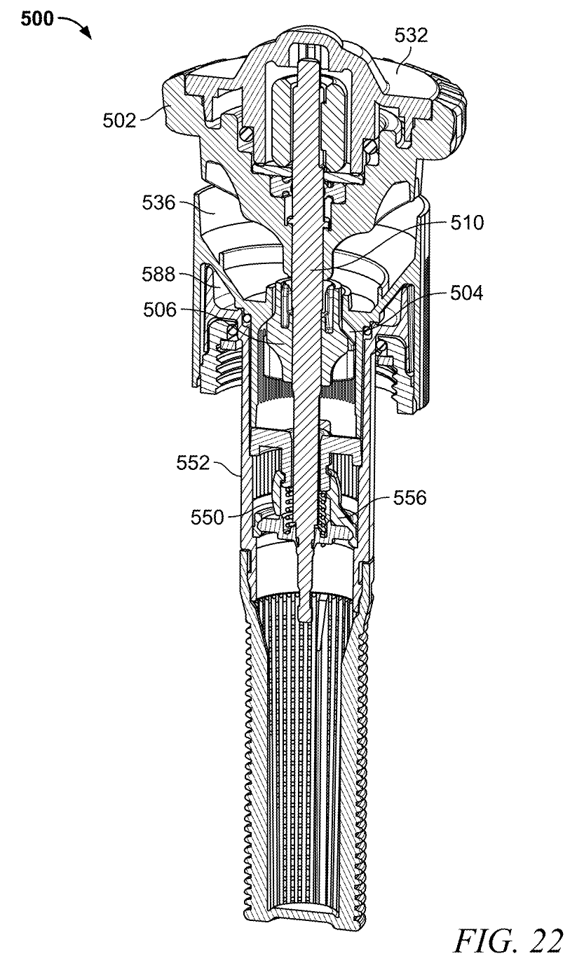

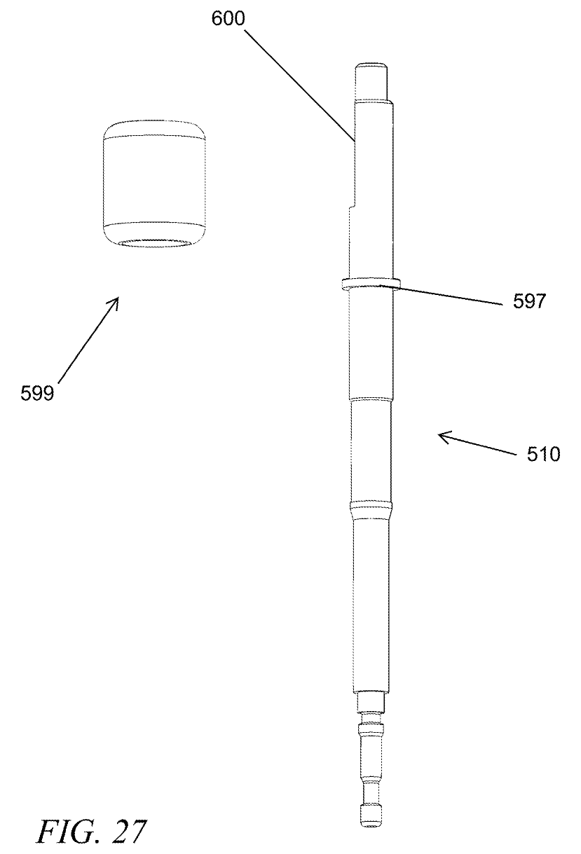

FIGS. 21-28 show another example of a nozzle 500 with a pop-up deflector 502. In one form, as can be seen from FIGS. 21 and 22, the nozzle 500 may include some of the same or similar components as the second embodiment above, i.e., nozzle 200. For instance, this example may use a radius adjustment valve 550 and throttle nut 556 that is the same or similar to the second embodiment above, i.e., nozzle 200 with radius adjustment valve 250 and throttle nut 256. This example includes numbering of reference numerals in the 500s corresponding generally to reference numerals of the second embodiment. Its pop-up operation is similar to that described above. The above description is generally incorporated into this description of this embodiment, except to the extent noted below.

This example of a nozzle 500 includes modified components relating to the valve sleeve 506, nozzle housing 536, and speed control brake. As addressed below, nozzle 500 includes the following features: (1) a valve sleeve 506 with internal axial ribs 581 for engaging the deflector 502 for adjustment of the arc of coverage; (2) the valve sleeve 506 having an external axial rib 584 to distinctly define an arcuate edge of the coverage pattern; (3) a nozzle housing 536 with a helical debris wall 585 and vent 586 to redirect debris away from the interior components of the nozzle 500; and (4) a viscous brake 590 disposed generally in the interior of the deflector 502 enclosed by cap 532. It should also be understood that one or more of these features may be added to any of the embodiments described above.

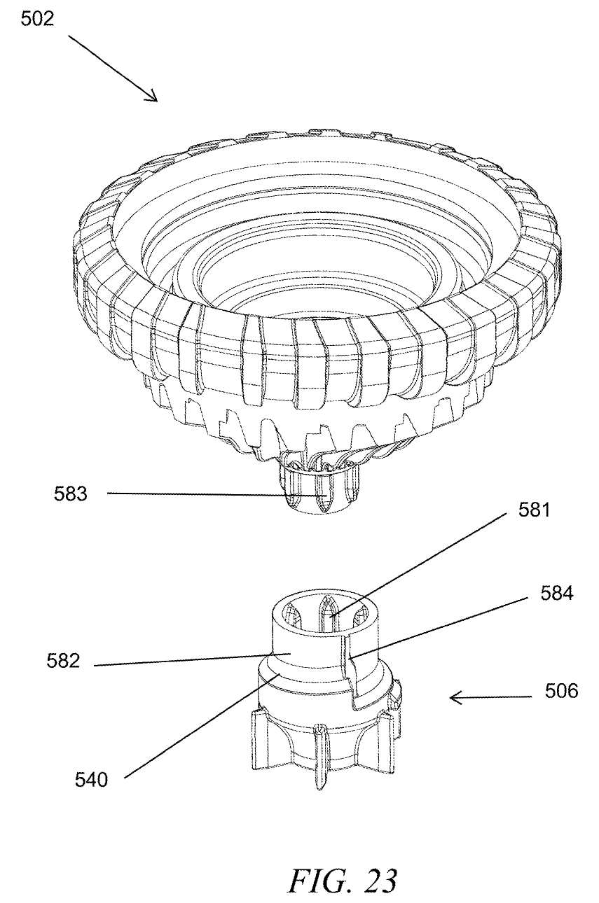

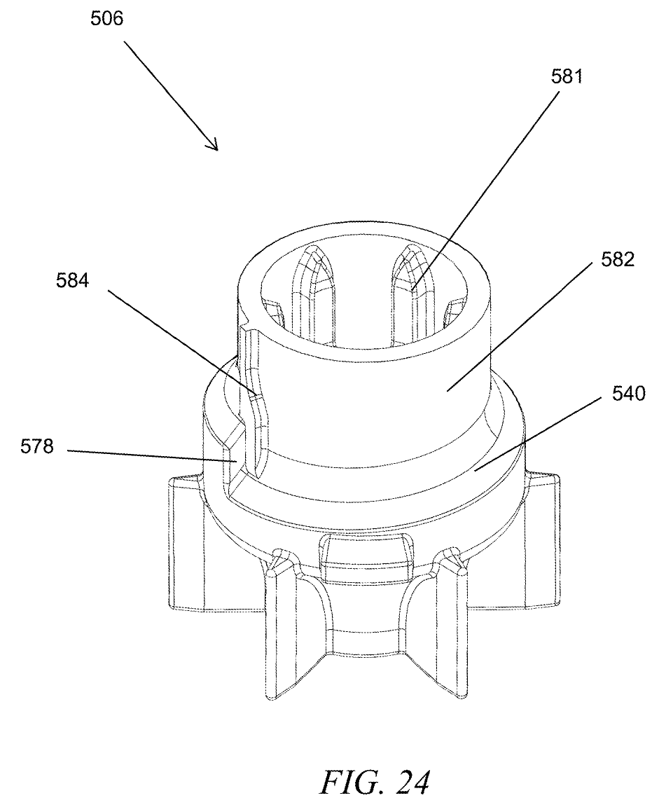

In one form, the manner of arc adjustment has been modified. As shown in FIGS. 23 and 24, the valve sleeve 506 includes internal axial ribs 581 that are spaced circumferentially about the central hub 582 that defines the bore of the valve sleeve 506. These internal axial ribs 581 may be used in lieu of the valve sleeve teeth used in earlier embodiments. The internal axial ribs 581 are sized and configured to engage corresponding external axial ribs 583 of the deflector 502 during arc adjustment. In other words, the bottom end of deflector 502 is modified to replace deflector teeth with the external axial ribs 583. When a user wants to adjust the arcuate setting of the nozzle 500, the user may push down on the deflector 502 so that each external axial rib 583 is received between two internal axial ribs 581 and may then rotate the deflector 502 to set the arc adjustment valve 504 to the desired arcuate setting.

In one form, the valve sleeve 506 also may include an external axial rib 584 that extends for much of the length of the central hub 582. As can be seen in FIGS. 23 and 24, in contrast to the internal axial ribs 581, the external axial rib 584 extends along the outside of the central hub 582. This external axial rib 584 may be added in addition to rib 578, which defines the ends of the helical surface 540. The external axial rib 584 generally extends in a downstream direction from the helical surface 540. As this external axial rib 584 extends for much of the length of the central hub 582, it is contemplated that this feature will generate a distinct or crisp boundary edge of the arcuate coverage pattern.

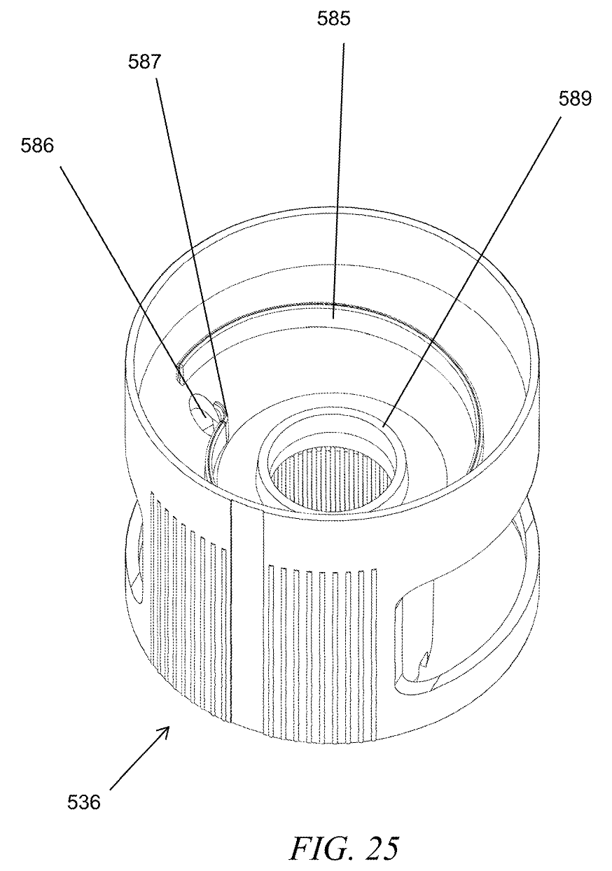

Next, in one form, the nozzle housing 536 may include a debris trap or debris diversion feature. As shown in FIG. 25, in one form, the nozzle housing 536 includes a helical debris wall 585 and a vent 586. It is contemplated that the interior of the nozzle 500 may be possibly exposed to debris during an irrigation cycle in which the deflector 502 is in an elevated, operational position. In one form, the helical debris wall 585 may define one helical coil or winding. Further, in one form, the helical debris wall 585 may guide any debris that is deposited or accumulates on a top surface (or upstream surface) of the nozzle housing 536 along the wall 585 until it reaches the vent 586. The vent 586 is generally in the form of an opening in the nozzle housing 536 disposed at the end of the helical debris wall 585. The helical debris wall 585 may include a curved end portion 587 at the vent 586 to prevent debris moving along the wall 585 from overshooting the vent 586.

Debris exiting the vent 586 is directed into a cavity 588 (FIG. 22) between the nozzle housing 536 and the nozzle collar 552, which is used as a debris pocket for the accumulation of debris. In this manner, debris may be diverted away from the arc adjustment valve 504 and other internal flow passages that might otherwise become clogged with debris. Further, the nozzle housing 536 may also include a second wall, such as an inner circular wall 589, which may further protect the interior of the nozzle 500 from debris.

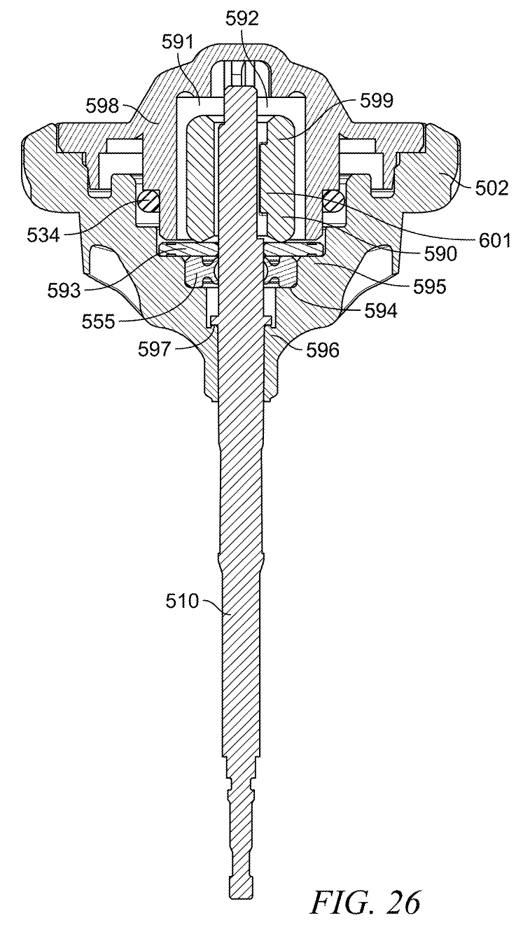

In addition, in one form, the speed control brake may be a viscous brake 590, rather than the brake components described above, e.g., friction disk 126, brake pad 128, and seal retainer 130. As shown in FIGS. 26-28, the viscous brake 590 is generally disposed in the interior of the deflector 502. The viscous brake 590 includes a chamber 591 that is defined by the cap 532 and a support disk 593. The chamber 591 is filled with a viscous fluid 592 that reduces the speed of the rotating deflector 502.

In one form, the deflector 502 may include a first annular ledge 594 that supports a seal member 555. It may further include a second annular ledge 595 disposed above the seal member 555 that supports the support disk 593. The support disk 593 is annular in shape with a bore to receive the shaft 510 therethrough. The support disk 593 acts as a floor of the chamber 591 holding the viscous fluid 592. The deflector 502 may further include a third annular ledge 596 to engage a flange 597 of the shaft 510 to limit upward movement of the deflector 502 relative to the shaft 510.

In one form, the cap 532 engages the deflector 502 to form a cover over the deflector 502. The cap 532 defines the sides and top of the chamber 591. It includes an annular wall 598 that defines the sides and creates a cylindrical shape to the chamber 591. In one form, the annular wall 598 is configured so that its bottom end engages (and is supported by) the outer circumference of the support disk 593. An o-ring or other seal member 534 may be disposed between the annular wall 598 and the deflector 502.

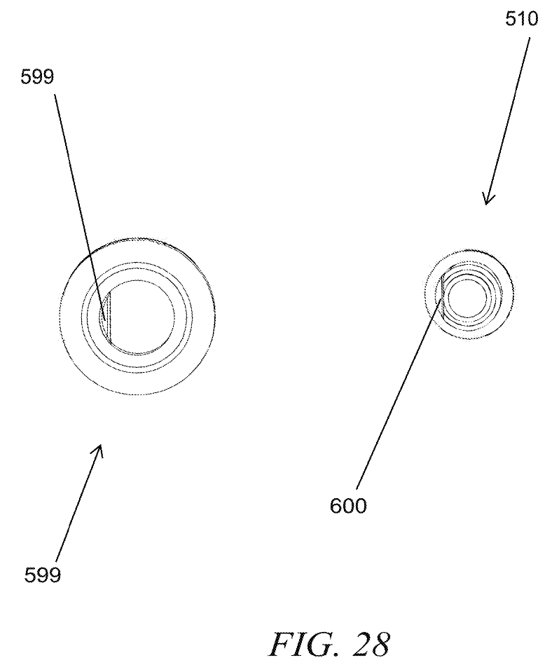

In one form, the chamber 591 contains the viscous fluid 592, a stator 599, and the top end of shaft 510. The stator 599 may be annular in shape with a bore therethrough and may extend axially around the top end of the shaft 510. As shown in FIG. 28, the shaft 510 includes a cutout portion or flat 600 that is sized and configured to engage a corresponding flange or flat 601 extending into the bore of the stator 599. The stator 599 is mounted about the shaft 510 such that the flats 600, 601 engage to hold the stator 599 stationary relative to the shaft 510 during operation. In other words, the shaft 510 and stator 599 remain stationary, while the deflector 502 and cap 532 rotate. The shear forces of the viscous fluid 592 act to reduce the rotational speed by interaction with the rotating cap 532 and stationary shaft 510 and stator 599.

It will be understood that various changes in the details, materials, and arrangements of parts and components which are herein described and illustrated in order to explain the nature of the nozzle may be made by those skilled in the art within the principle and scope of the subject matter as expressed in the appended claims. Furthermore, while various features are described with regard to a particular embodiment or a particular approach, it will be appreciated that features described for one embodiment also may be incorporated with the other described embodiments.

What is claimed is:

1. A nozzle comprising:
a deflector movable between an extended position and a retracted position, the deflector having a surface redirecting fluid impacting the surface outwardly from the deflector in the extended position;
a flow path between an inlet and an arcuate outlet, the arcuate outlet oriented to direct exiting fluid against the surface of the deflector; and
an arc adjustment valve along the flow path adjustable to change a length of the arcuate outlet for distribution of fluid in an arc of distribution, the valve comprising a first valve surface and a second valve surface;
wherein the first valve surface and the second valve surface define the arcuate outlet therebetween and engage one another at least in part when the deflector is in the extended position and wherein the first and second valve surfaces are spaced from one another when the deflector is in the retracted position.

2. The nozzle of claim 1, further comprising:
a first valve body having the first valve surface and a second valve body having the second valve surface, the first and second valve surfaces being helical.

3. The nozzle of claim 2, wherein the deflector is movable from the extended position to an adjustment position in which the deflector is configured to engage and rotate the first valve body to set the length of the arcuate outlet.

4. The nozzle of claim 2, wherein the first valve body comprises a plurality of fins and the second valve body comprises a grooved surface, the plurality of fins engaging the grooved surface to guide axial movement of the first valve body.

5. The nozzle of claim 1, further comprising:
a spring operatively coupled to the deflector to bias the deflector to the retracted position;
wherein fluid flow along the flow path overcomes a bias of the spring to move the deflector to the extended position and wherein the bias of the spring moves the deflector to the retracted position in absence of fluid flow along the flow path.

6. The nozzle of claim 5, further comprising a shaft supporting the deflector, the spring operatively coupled to the shaft to cause the deflector to move from the extended position to the retracted position.

7. The nozzle of claim 6, further comprising:
a first valve body having the first valve surface and a second valve body having the second valve surface, the first valve body engaging the shaft;
wherein the first valve body is configured to move between an engaged position and a disengaged position relative to the second valve body in conjunction with movement of the deflector between the extended position and the retracted position, respectively.

8. The nozzle of claim 1, wherein:
the deflector is configured for rotation in response to fluid impacting the surface of the deflector;
the deflector comprises an interior defining, at least in part, a chamber; and
a brake is disposed in the chamber to control speed of rotation of the deflector.

9. The nozzle of claim 2, further comprising:
a wall forming at least a portion of a helix, the wall disposed on an upstream surface of the second valve body; and
a vent in the upstream surface of the second valve body at an end of the wall.

10. A nozzle comprising:
a deflector movable between an extended position and a retracted position, the deflector having a surface redirecting fluid impacting the surface outwardly from the deflector in the extended position;
a flow path between an inlet and an outlet, the outlet oriented to direct exiting fluid against the surface of the deflector;
a flow adjustment valve comprising a first valve body and a second valve body, one of the first valve body and the second valve body being rotatable relative to the other of the first valve body and the second valve body to adjust flow along the flow path; and
a spring engaging at least one of the first valve body and the second valve body and operatively coupled to the deflector, the spring biased to urge the deflector to the retracted position.

11. The nozzle of claim 10, wherein the first valve body and the second valve body move in conjunction with one another between an extended position in response to fluid flow along the flow path and a retracted position in response to bias of the spring.

12. The nozzle of claim 10, wherein:
the first valve body engages a nozzle collar portion that is rotatable about a central axis of the nozzle, the first valve body rotating in conjunction with the nozzle collar portion.

13. The nozzle of claim 12, wherein the second valve body is fixed against rotation, the second valve body engaging the first valve body and being disposed downstream of the first valve body.

14. The nozzle of claim 13, wherein the first valve body comprises a first set of flow openings and the second valve body comprises a second set of flow openings, the first valve body being rotatable relative to the second valve body to align the first and second set of flow openings or to partially or completely block fluid flow through the first and second set of flow openings.

15. The nozzle of claim 12, wherein the first valve body is configured to move upstream towards the second valve body upon rotation of the nozzle collar portion in a first direction and to move downstream away from the second valve body upon rotation of the nozzle collar portion in a second, opposite direction.

16. The nozzle of claim 15, wherein the first valve body comprises one or more flow openings and wherein the second valve body partially or completely blocks the one or more flow openings upon rotation of the nozzle collar portion in the first direction.

17. A nozzle assembly comprising:
a deflector having a surface redirecting fluid impacting the surface outwardly from the deflector;
a flow path between an inlet and an outlet, the outlet oriented to direct exiting fluid against the surface of the deflector;
a sleeve defining, at least in part, a pressure chamber;
a first spring disposed in the pressure chamber and biasing the sleeve; and
a first air passage venting air from the pressure chamber;
wherein the sleeve is movable in response to fluid pressure against a bias of the first spring to decrease fluid flow along the flow path.

18. The nozzle assembly of claim 17, further comprising:
a plate spaced upstream from the sleeve and defining, in combination with the sleeve, a gap between the plate and the sleeve;
wherein the sleeve is movable in response to fluid pressure toward the plate, reducing a size of the gap and reducing flow along the flow path.

19. The nozzle assembly of claim 18, further comprising a second spring engaging the plate, the second spring operatively coupled to the deflector to bias the deflector toward a retracted position.

20. The nozzle assembly of claim 19, further comprising a shaft engaging the plate and supporting the deflector, the shaft moving the deflector between the retracted position and an extended position.

21. The nozzle assembly of claim 17, further comprising:
a stem comprising a wall defining a conduit for fluid flow and comprising a second air passage through the wall;
wherein a nozzle is mounted at a downstream end of the stem with at least a portion of the nozzle extending into the conduit, the nozzle comprising the deflector, the sleeve, and the first spring.

22. The nozzle assembly of claim 21, further comprising:
a stem seal disposed between the nozzle and the wall of the stem and blocking fluid flow through a portion of the conduit, the stem seal defining a chamber connecting the first air passage to the second air passage.
